(19) United States
(12) Patent Application Publication
(10) Pub. No.: US 2024/0213070 A1
(43) Pub. Date: Jun. 27, 2024

(54) ROTATIONAL INDEXERS WITH WAFER CENTERING CAPABILITY

(71) Applicant: Lam Research Corporation, Fremont, CA (US)

(72) Inventors: Brian Lewis Ratliff, Hillsboro, OR (US); Richard M. Blank, San Jose, CA (US); Stephen Topping, Portland, OR (US); Karl Frederick Leeser, West Linn, OR (US)

(21) Appl. No.: 18/556,910

(22) PCT Filed: Apr. 22, 2022
(86) PCT No.: PCT/US2022/026049

§ 371 Date: Oct. 24, 2023

Related U.S. Application Data
(60) Provisional application No. 63/201,390, filed on Apr. 27, 2021.

(51) Int. Cl. H01L 21/68; G05B 19/4099; H01L 21/687

(52) U.S. Cl. CPC H01L 21/68; G05B 19/4099; H01L 21/68742; H01L 21/68764; H01L 21/68771; H01L 21/68792; G05B 2219/45031

(57) ABSTRACT

Rotational indexers are provided that allow for wafer-by-wafer centering to be performed in association with each wafer pedestal-to-pedestal transfer operation within a multi-station chamber. One such rotational indexer has a rotational center axis that is movable along one or more lateral directions in order to provide wafer centering capability; sealing arrangements with lateral movement capability are provided for such implementations. Another such rotational indexer uses additional rotational capability at the wafer supports of the indexer, in combination with deliberate off-center placement of the wafers on the wafer supports of the indexer, to provide wafer centering capability.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools commonly include one or more semiconductor processing chambers that provide an isolated environment within which to process semiconductor wafers. In some semiconductor processing tools, multiple semiconductor wafers may be processed within a single chamber. In such semiconductor processing tools, such a chamber may include a plurality of wafer processing stations, each having its own wafer support or pedestal and, for example, gas distributor positioned thereabove.

One common architecture for such multi-station chambers is the quad-station module (QSM), which features four wafer processing stations arranged in a square pattern within a single, large chamber. A rotational indexer is typically provided in such QSM tools to allow wafers to be moved from station to station within the processing chamber (each station having a corresponding pedestal and the pedestals being laid out in a circular array centered on the indexer's axis of rotation). In some such QSM tools, features may be provided that allow for some degree of isolation between wafer stations, e.g., inert gas curtains may be provided in between wafer stations to reduce the chances of processing gases migrating from one wafer station to another.

A rotational indexer typically includes a rotational drive mechanism that has a rotational output to which a central hub is affixed. The central hub has a plurality of indexer arms that are arranged in a circular array centered on the axis of rotation of the central hub; each such arm has a proximal end that is connected with the central hub and a distal end at a location radially outward from the central hub which has a wafer support that is used to support a semiconductor processing wafer. In a QSM tool, an indexer with four indexer arms, each perpendicular to its neighbors, may be used to transfer wafers between the four wafer processing stations.

A more advanced rotational indexer is described in U.S. Pat. No. 10,109,517 and features additional rotational axes that allow for the wafer supports at the distal ends of the indexer arms to be rotated in unison relative to the indexer arms, thereby allowing the wafers to not only be rotated about the rotational center of the indexer, but also rotated about their own centers relative to the indexer.

### SUMMARY

The present inventors conceived of various techniques and systems that may be used to provide indexers that are able to fine-tune the placement of wafers on pedestals. In a typical indexer, wafers are generally placed on the indexer, transferred to new wafer processing stations, and then removed from the indexer in unison. As a result, such indexers are unable to adjust for wafer and/or pedestal positioning errors. For example, if a wafer slips 1 mm off center while being moved between two wafer processing stations by an indexer, that wafer will typically be 1 mm off center with respect to each subsequent pedestal that it is placed upon with in the tool (assuming that the pedestals at all of the wafer processing stations are positioned correctly). Similarly, if one of the pedestals is offset by 1 mm from its ideal position, every wafer placed thereupon relative to the assumed ideal position will be 1 mm off-center. While the errors in placement of wafers and/or pedestals may be quite small, such errors may nonetheless contribute to reduced wafer yield and degraded wafer uniformity.

The present inventors conceived of various techniques, systems, and mechanisms for correcting for such positioning errors. Two general approaches were developed, both incorporating a similar concept but attacking the issue from opposite ends of the indexer arms.

The first approach involves a technique that may be practiced using a rotational indexer such as is described in U.S. Pat. No. 10,109,517, which is hereby incorporated herein by reference in its entirety. As discussed above, the rotational indexers described in U.S. Pat. No. 10,109,517, which may be referred to herein as additional rotational axis (ARA) indexers, have the ability to rotate the indexer arms, as well as the rotatable wafer supports and the wafers supported thereon, about a first axis (which is typically positioned in the center of an array of wafer processing stations). Such indexers also have the ability to rotate the rotatable wafer supports about corresponding second axes relative to the indexer arms. The rotatable wafer supports may, for example, be caused to rotate by tie-rods that link each rotatable wafer support to a second hub that is able to be rotated about the rotational axis of the ARA indexer relative to the central hub of the indexer which supports the indexer arms; relative rotation between the central hub and the second hub may cause the tie-rods to actuate the rotatable wafer supports and cause them to rotate relative to the indexer arms. The two hubs may be driven by two different motors, with the drive shafts thereof being coaxially arranged.

ARA indexers are typically operated using a “center pick” paradigm in which the control systems for such indexers are configured to control the rotation of the indexer about the first axis so as to cause the second axes thereof to be, on average, as close as possible to the centers of the pedestals (and thus presumably the centers of the wafers) in the tool as possible. If no errors are present in pedestal positioning, wafer positioning, or indexer positioning, then such actions will result in the wafers being perfectly centered on the second axes and also placed in a perfectly centered manner on each pedestal.

The present inventors determined that by operating ARA indexers in an “off-center pick” paradigm, i.e., deliberately controlling the rotation of the indexer about the first axis so that the second axes of the indexer arms are offset from the pedestal centers by some distance and then placing the wafers on the rotatable wafer supports of such an ARA indexer so that the centers of the wafers supported by the rotatable wafer supports thereof were also deliberately off-center with respect to the corresponding second axes of those rotatable wafer supports, it was then possible to, through a rotation of the indexer about the first axis and/or rotation of the rotatable wafer supports of the indexer about the corresponding second axes, adjust the placement of the presumed wafer center point relative to the pedestal on which it was being placed. Such a technique may be used to sequentially adjust the placement of each wafer until all of the wafers have been placed.

A similar technique was also conceived of in which the indexer system incorporated additional components that facilitated the introduction of a controllable lateral offset between the first axis of the indexer and the pedestals on which the indexer may be configured to place a wafer. Such techniques may be implemented using either ARA or non-ARA indexers, and allow either type of indexer to fine-tune the placement of wafers within the tool during indexing operations. Thus, the shaft(s) of the rotational indexer that is/are centered on the first axis are able to not only rotate to rotate the indexer hub and arms to effect wafer transfers from pedestal to pedestal of the wafer processing stations, but may also be laterally translated in one or more directions perpendicular to the first axis to facilitate fine-tuning the placement of each wafer on the respective destination pedestal. For clarity, “lateral” or “laterally,” in the context of this disclosure, refers to a direction or directions that are perpendicular to the first axis of the indexer, i.e., the rotational axis of the indexer. Thus, for example, if the indexer is installed so that the first axis of the indexer is vertical, a lateral direction, lateral axis, or lateral movement would be a horizontal direction, axis, or movement in such a configuration, e.g., a radial direction or a direction that is parallel to a radial direction.

In indexer systems in which the first axis of the indexer is able to be translated laterally, special sealing arrangements may be used to provide a vacuum-tight seal across a mechanical interface which sees both rotational and translational movement.

Various aspects of such systems and techniques are discussed below in more detail and include, but are not limited to, the various implementations discussed below.

In some implementations, an apparatus may be provided that includes a chamber, a plurality of N semiconductor processing stations arranged in a nominally circular pattern within the chamber, and a rotational indexer having a central hub and a plurality of N indexer arms, the central hub rotatable relative to the chamber about a first axis nominally located at the center of the circular pattern, each indexer arm having a proximal end fixedly mounted to the central hub and a distal end that supports a rotatable wafer support that is configured to rotate about a corresponding second axis relative to the indexer arms. Each semiconductor processing station may have a corresponding pedestal associated with a corresponding target location, and the corresponding target location of each pedestal may be representative of a location which, when a wafer is placed on that pedestal and centered on that pedestal's corresponding target location, results in that wafer being considered centered on that pedestal for a given semiconductor wafer processing operation. The apparatus may further include a controller that includes one or more memory devices and one or more processors. The one or more memory devices and the one or more processors may be operatively connected and the one or more memory devices may store computer-executable instructions which, when executed by the one or more processors, cause the one or more processors to: a) select an embarkation pedestal from the plurality of pedestals, b) select a destination pedestal from the plurality of pedestals, c) select a selected rotatable wafer support from the plurality of rotatable wafer supports, d) cause at least one of the central hub and the selected rotatable wafer support to rotate about the first axis and to rotate about the second axis of the selected rotatable wafer support relative to the indexer arms, respectively, such that a corresponding reference point that is fixed with respect to the selected rotatable wafer support and offset from the second axis of the selected rotatable wafer support by a first non-zero distance in a direction perpendicular to the second axis of the selected rotatable wafer support is centered on an estimated center of a wafer located at the semiconductor processing station associated with the embarkation pedestal when viewed along a direction parallel to the first axis, e) cause the wafer located at the semiconductor processing station associated with the embarkation pedestal to be placed on the selected rotatable wafer support after the corresponding reference point for the selected rotatable wafer support is centered on the estimated center of the wafer located at the semiconductor procession station associated with the embarkation pedestal when viewed along the a direction parallel to the first axis, f) cause at least one of the central hub and the selected rotatable wafer support to rotate about the first axis and to rotate about the second axis of the selected rotatable wafer support relative to the indexer arms, respectively, such that the corresponding reference point for the selected rotatable wafer support is centered above the corresponding target location of the destination pedestal, and g) cause the wafer on the selected rotatable wafer support to be lifted off of the selected rotatable wafer support after the corresponding reference point for the selected rotatable wafer support is centered above the corresponding target location of the destination pedestal.

In some implementations of the apparatus, the one or more memory devices may further store additional computer-executable instructions which, when executed by the one or more processors, cause the one or more processors to, for a given set of M wafers, perform (a) through (g) M times, once for each wafer, wherein 2≤M≤N.

In some implementations of the apparatus, one or more memory devices may further store additional computer-executable instructions which, when executed by the one or more processors, cause the one or more processors to cause at least some rotation of the central hub about the first axis to occur for at least part of (d) and at least part of (f) simultaneously for all M wafers.

In some implementations of the apparatus, the one or more memory devices may further store additional computer-executable instructions which, when executed by the one or more processors, cause at least one of the following to occur: (e) to be performed at different times for at least two of the M wafers and (g) to be performed at different times for at least two of the M wafers.

In some of the above implementations of the apparatus, N may equal 4 and M may be 3 or 4.

In some implementations of the apparatus, the first distance may be selected to be larger than twice an estimated maximum pedestal location tolerance within the chamber.

In some implementations of the apparatus, the one or more memory devices may further store additional computer-executable instructions which, when executed by the one or more processors, cause the one or more processors to, for (d), use the corresponding target location of the embarkation pedestal as the estimated center of the wafer located at the semiconductor processing station associated with the embarkation pedestal.

In some implementations of the apparatus, the apparatus may further include, for each semiconductor processing station, one or more corresponding wafer position sensors configured to obtain information from which a location of the center of a wafer placed on the pedestal of the corresponding semiconductor processing station can be determined. In such implementations, the one or more memory devices may further store additional computer-executable instructions which, when executed by the one or more processors, cause the one or more processors to: h) determine, prior to (e), the location of the center of the wafer located at the semiconductor processing station associated with the embarkation pedestal using the information from the wafer position sensors for the corresponding wafer processing station, and i) use, in (d), the location of the center of the wafer as determined in (h) as the estimated center of the wafer located at the semiconductor processing station associated with the embarkation pedestal.

In some implementations of the apparatus, the positions of the second axes relative to the central hub may not be movable responsive to control signals caused to be sent by the one or more processors and no part of each rotatable wafer support may be movable relative to the remainder of that rotatable wafer support responsive to control signals caused to be sent by the one or more processors.

In some implementations of the apparatus, the apparatus may include, at each semiconductor processing station, a corresponding lift pin mechanism with a corresponding plurality of lift pins. Each lift pin mechanism may be configured to controllably extend and retract the corresponding plurality of lift pins such that uppermost surfaces of the corresponding plurality of lift pins are movable between at least locations above and below an uppermost surface of the pedestal of the corresponding semiconductor processing station.

In some implementations of the apparatus, the one or more memory devices may further store additional computer-executable instructions which, when executed by the one or more processors, cause the one or more processors to, prior to performing (f): h) cause any wafers being supported by the rotatable wafer supports other than the selected rotatable wafer support to each be placed on the lift pins of a corresponding one of the semiconductor processing stations, and i) place one of the wafers on the selected rotatable wafer support when the selected rotatable wafer support is not supporting one of the wafers.

In some implementations of the apparatus, the one or more memory devices may further store additional computer-executable instructions which, when executed by the one or more processors, cause the one or more processors to control the rotational indexer such that the indexer arms and the rotatable wafer supports are in a first configuration immediately prior to performing (h) and immediately before (i).

In some implementations, one or more non-transitory, computer-readable media storing computer-executable instructions for controlling one or more processors of a semiconductor processing tool may be provided. Such a semiconductor processing tool may, for example, have a chamber with a plurality of N semiconductor processing stations, each having a corresponding pedestal with a corresponding target location, arranged therewithin and a rotational indexer having a central hub and a plurality of N indexer arms each having a distal end that supports a corresponding rotatable wafer support. The computer-executable instructions, when executed, may cause the one or more processors to: a) select an embarkation pedestal from the plurality of pedestals, b) select a destination pedestal from the plurality of pedestals, c) select a selected rotatable wafer support from the plurality of rotatable wafer supports, d) cause at least one of the central hub and the selected rotatable wafer support to rotate about the first axis and to rotate about the second axis of the selected rotatable wafer support relative to the indexer arms, respectively, such that a corresponding reference point that is fixed with respect to the selected rotatable wafer support and offset from the second axis of the selected rotatable wafer support by a first non-zero distance in a direction perpendicular to the second axis of the selected rotatable wafer support is centered on an estimated center of a wafer located at the semiconductor processing station associated with the embarkation pedestal when viewed along a direction parallel to the first axis, e) cause the wafer located at the semiconductor processing station associated with the embarkation pedestal to be placed on the selected rotatable wafer support after the corresponding reference point for the selected rotatable wafer support is centered on the estimated center of the wafer located at the semiconductor procession station associated with the embarkation pedestal when viewed along a direction parallel to the first axis, f) cause at least one of the central hub and the selected rotatable wafer support to rotate about the first axis and to rotate about the second axis of the selected rotatable wafer support relative to the indexer arms, respectively, such that the corresponding reference point for the selected rotatable wafer support is centered above the corresponding target location of the destination pedestal, and g) cause the wafer on the selected rotatable wafer support to be lifted off of the selected rotatable wafer support after the corresponding reference point for the selected rotatable wafer support is centered above the corresponding target location of the destination pedestal.

In some implementations of the one or more non-transitory, computer-readable media, the one or more non-transitory, computer-readable media may further store additional computer-executable instructions which, when executed by the one or more processors, cause the one or more processors to, for a given set of M wafers, perform (a) through (g) M times, once for each wafer, wherein 2≤M≤N.

In some implementations of the one or more non-transitory, computer-readable media, the one or more non-transitory, computer-readable media may further store additional computer-executable instructions which, when executed by the one or more processors, cause the one or more processors to cause at least some rotation of the central hub about the first axis to occur for at least part of (d) and at least part of (f) simultaneously for all M wafers.

In some implementations of the one or more non-transitory, computer-readable media, the one or more non-transitory, computer-readable media may further store additional computer-executable instructions which, when executed by the one or more processors, cause at least one of the following to occur: (e) to be performed at different times for at least two of the M wafers and (g) to be performed at different times for at least two of the M wafers.

In some of the above implementations of the one or more non-transitory, computer-readable media, N may equal 4 and M may equal 3 or 4.

In some implementations of the one or more non-transitory, computer-readable media, the first distance may be selected to be larger than twice an estimated maximum pedestal location tolerance within the chamber.

In some implementations of the one or more non-transitory, computer-readable media, the one or more non-transitory, computer-readable media may further store additional computer-executable instructions which, when executed by the one or more processors, cause the one or more processors to, for (d), use the corresponding target location of the embarkation pedestal as the estimated center of the wafer located at the semiconductor processing station associated with the embarkation pedestal.

In some implementations of the one or more non-transitory, computer-readable media, the one or more non-transitory, computer-readable media may further store additional computer-executable instructions which, when executed by the one or more processors, cause the one or more processors to: h) determine, prior to (e), the location of the center of the wafer located at the semiconductor processing station associated with the embarkation pedestal using information from one or more wafer position sensors for the corresponding wafer processing station, and i) use, in (d), the location of the center of the wafer as determined in (h) as the estimated center of the wafer located at the semiconductor processing station associated with the embarkation pedestal.

In some implementations of the one or more non-transitory, computer-readable media, the one or more non-transitory, computer-readable media may further store additional computer-executable instructions which, when executed by the one or more processors, cause the one or more processors to, prior to performing (f): h) cause any wafers being supported by the rotatable wafer supports other than the selected rotatable wafer support to each be placed on lift pins of a corresponding one of the semiconductor processing stations, and i) place one of the wafers on the selected rotatable wafer support when the selected rotatable wafer support is not supporting one of the wafers.

In some implementations of the one or more non-transitory, computer-readable media, the one or more non-transitory, computer-readable media may further store additional computer-executable instructions which, when executed by the one or more processors, cause the one or more processors to control the rotational indexer such that the indexer arms and the rotatable wafer supports are in a first configuration immediately prior to performing (h) and immediately before (i).

In some implementations, an apparatus may be provided that includes a rotational indexer arm assembly having a central hub and a plurality of N indexer arms arranged in a circular pattern about a first axis, a shaft that is fixed with respect to the central hub, a motor having a motor housing, and a lateral movement mechanism. In such implementations, the N indexer arms may each be fixed in space relative to the central hub, the shaft and the rotational indexer arm assembly may be configured to rotate relative to the motor housing and about the first axis responsive to actuation of the motor, and the lateral movement mechanism may be configured to controllably cause the shaft, and thus the first axis, to move in at least one direction perpendicular to the first axis responsive to receipt of one or more input signals.

In some implementations of the apparatus, the first axis may have a maximum lateral displacement capability in the at least one direction perpendicular to the first axis that is no more than 200 mm. In some further such implementations of the apparatus, the first axis may have a maximum lateral displacement capability in the at least one direction perpendicular to the first axis that is no more than 20 mm. In some additional further such implementations of the apparatus, the first axis may have a maximum lateral displacement capability in the at least one direction perpendicular to the first axis that is no more than 2 mm.

In some implementations of the apparatus, the apparatus may further include a chamber with an interior volume housing the indexer arm assembly and a rotational and translational seal mechanism that has a first portion that is fixed in space relative to the shaft, a second portion that is fixed in space relative to the chamber, and one or more third portions arranged to provide a seal interface between the first portion and the second portion. The seal interface provided by the one or more third portions may be maintained during rotation of the first portion of the rotational and translational seal mechanism relative to the second portion of the rotational and translational seal mechanism and during at least some translation of the first portion of the rotational and translational seal mechanism relative to the second portion of the rotational and translational seal mechanism and along a direction perpendicular to the first axis.

In some implementations of the apparatus, the rotational and translational seal mechanism may include a rotational seal having a corresponding first portion, and a bellows seal having a first end, a second end, and a flexible bellows portion spanning between the first end of the bellows seal and the second end of the bellows seal. The first end of the bellows seal may be fixed in space relative to the chamber and the second end of the bellows seal may be fixed in space relative to the first portion of the rotational seal, and the shaft may be rotatable about the first axis relative to the first portion of the rotational seal.

In some implementations of the apparatus, the rotational seal may be a ferrofluidic seal.

In some implementations of the apparatus, the rotational and translational seal mechanism may include a first eccentric mount portion, a first rotational interface, and a second rotational interface. The first rotational interface may have a corresponding first portion that is fixed in space with respect to the central hub and a corresponding second portion that is fixed in space with respect to the first eccentric mount portion. Additionally, the second rotational interface may have a corresponding first portion that is fixed in space with respect to the first eccentric mount portion and a corresponding second portion that is configured to be rotatable relative to the first eccentric mount portion. Furthermore, the first portion of the first rotational interface and the second portion of the first rotational interface may be rotatable relative to each other about the first axis, the first portion of the second rotational interface and the second portion of the second rotational interface may be rotatable relative to each other about a second axis, the first rotational interface may include a first rotational seal that seals between the first portion of the first rotational interface and the second portion of the first rotational interface, the second rotational interface may include a second rotational seal that seals between the first portion of the second rotational interface and the second portion of the second rotational interface, and the first axis and the second axis may be parallel to each other and offset from one another by a first non-zero distance along a direction perpendicular to the first axis.

In some implementations of the apparatus, the first portion of the first rotational seal may be part of the shaft.

In some implementations of the apparatus, the first axis and the second axis may both be encircled by the second rotational seal.

In some implementations of the apparatus, the first rotational seal and the second rotational seal may both be ferrofluidic seals.

In some implementations of the apparatus, the rotational and translational seal mechanism may further include a second eccentric mount portion and a third rotational interface. In such implementations, the second portion of the second rotational interface may be fixed in space with respect to the second eccentric mount portion, the third rotational interface may have a corresponding first portion that is fixed in space with respect to the second eccentric and a corresponding second portion that is configured to be rotatable relative to the second eccentric mount portion, the first portion of the third rotational interface and the second portion of the third rotational interface may be rotatable relative to each other about a third axis, the third rotational interface may include a third rotational seal that seals between the first portion of the third rotational interface and the second portion of the third rotational interface, and the third axis may be parallel to the first axis and the second axis and may be offset from the second axis by a second non-zero distance along a direction perpendicular to the second axis.

In some implementations of the apparatus, the apparatus may further include a lift actuator and a bellows seal having a first end, a second end, and a flexible bellows portion spanning between the first end of the bellows seal and the second end of the bellows seal. In such implementations, the first end of the bellows seal may be fixedly mounted with respect to the shaft, the second end of the bellows seal may be fixedly mounted with respect to the first portion of the first rotational interface, and the lift actuator may be configured to cause the shaft to move along the first axis when actuated.

In some implementations of the apparatus, the apparatus may further include a lift actuator and a bellows seal having a first end, a second end, and a flexible bellows portion spanning between the first end of the bellows seal and the second end of the bellows seal. In such implementations, the first end of the bellows seal may be fixedly mounted with respect to the chamber, the second end of the bellows seal may be fixedly mounted with respect to the motor housing, and the lift actuator may be configured to cause the motor housing, the shaft, and at least the first rotational interface and the second rotational interface to move along the first axis when actuated.

In some implementations of the apparatus, the apparatus may also include a chamber with an interior volume housing the indexer arm assembly.

In some such implementations of the apparatus, the apparatus may further include a plurality of N semiconductor processing stations arranged in a nominally circular pattern within the interior volume of the chamber, each semiconductor processing station having a corresponding pedestal and each pedestal having a corresponding target location. The corresponding target location of each pedestal may be representative of a location which, when a wafer is placed on that pedestal and centered on that pedestal's corresponding target location, results in that wafer being considered centered on that pedestal for a given semiconductor wafer processing operation. The apparatus may also further include a controller including one or more memory devices and one or more processors. The one or more memory devices and the one or more processors may be operatively connected and the one or more memory devices may store computer-executable instructions which, when executed by the one or more processors, cause the one or more processors to: a) select an embarkation pedestal from the plurality of pedestals, b) select a destination pedestal from the plurality of pedestals, c) select a selected wafer support from the plurality of wafer supports, d) cause at least one action to occur that is selected from the group consisting of i) actuation of the motor so as to cause the central hub to rotate relative to the chamber and about the first axis, ii) actuation of the lateral movement mechanism so as to cause the first axis to move laterally relative to the chamber, and iii) both (i) and (ii) such that a corresponding reference point that is fixed with respect to the selected wafer support is centered on an estimated center of a wafer located at the semiconductor processing station associated with the embarkation pedestal when viewed along a direction parallel to the first axis, e) cause the wafer located at the semiconductor processing station associated with the embarkation pedestal to be placed on the selected wafer support after the corresponding reference point for the selected wafer support is centered on the estimated center of the wafer located at the semiconductor procession station associated with the embarkation pedestal when viewed along a direction parallel to the first axis, f) cause at least one action to occur that is selected from the group consisting of i) actuation of the motor so as to cause the central hub to rotate relative to the chamber and about the first axis and ii) actuation of the motor so as to cause the central hub to rotate relative to the chamber and about the first axis and actuation of the lateral movement mechanism so as to cause the first axis to move laterally relative to the chamber such that the corresponding reference point for the selected wafer support is centered above the corresponding target location of the destination pedestal, and g) cause the wafer on the selected wafer support to be lifted off of the selected wafer support after the corresponding reference point for the selected wafer support is centered above the corresponding target location of the destination pedestal.

In some implementations of the apparatus, the one or more memory devices may further store additional computer-executable instructions which, when executed by the one or more processors, cause the one or more processors to, for a given set of M wafers, perform (a) through (g) M times, once for each wafer, wherein 2≤M≤N.

In some implementations of the apparatus, the one or more memory devices may further store additional computer-executable instructions which, when executed by the one or more processors, cause the one or more processors to cause at least some rotation of the central hub about the first axis to occur for at least part of (d) and at least part of (f) simultaneously for all M wafers.

In some implementations of the apparatus, the one or more memory devices may further store additional computer-executable instructions which, when executed by the one or more processors, cause at least one of the following to occur: (e) to be performed at different times for each of the M wafers and (g) to be performed at different times for each of the M wafers.

In some implementations of the apparatus, N may equal 4 and M may be either 3 or 4.

In some implementations of the apparatus, the one or more memory devices may further store additional computer-executable instructions which, when executed by the one or more processors, cause the one or more processors to, for (d), use the corresponding target location of the embarkation pedestal as the estimated center of the wafer located at the semiconductor processing station associated with the embarkation pedestal.

In some implementations of the apparatus, the apparatus may, for each semiconductor processing station, include one or more corresponding wafer position sensors configured to determine a location of the center of a wafer placed on the pedestal of the corresponding semiconductor processing station. In such implementations, the one or more memory devices may further store additional computer-executable instructions which, when executed by the one or more processors, cause the one or more processors to: h) cause the corresponding wafer position sensors for the semiconductor processing station having the embarkation pedestal to determine, prior to (d), the location of the center of the wafer while the wafer is resting on the embarkation pedestal, and i) use, in (d), the location of the center of the wafer as determined in (h) as the estimated center of the wafer located at the semiconductor processing station associated with the embarkation pedestal.

In some implementations of the apparatus, the apparatus may further include, at each semiconductor processing station, a corresponding lift pin mechanism with a corresponding plurality of lift pins, each lift pin mechanism configured to controllably extend and retract the corresponding plurality of lift pins such that uppermost surfaces of the corresponding plurality of lift pins are movable between at least locations above and below an uppermost surface of the pedestal of the corresponding semiconductor processing station.

Details of one or more implementations of the subject matter described in this specification, including but not limited to those set forth above, are set forth in the accompanying drawings and the description below. Other features, aspects, and advantages will become apparent from the description, the drawings, and the claims.

### BRIEF DESCRIPTION OF THE DRAWINGS

It will be appreciated that the Figures discussed herein are merely intended to provide a reference for discussion and are not intended to limit the present disclosure. Other implementations not specifically depicted herein but evident from the totality of the disclosure are also intended to be within the scope of the disclosure.

FIG. 1 depicts an example of a multi-station chamber with a rotational indexer system.

FIG. 2 depicts a diagonal section view of the multi-station chamber of FIG. 1.

FIG. 3 depicts an example of a multi-station chamber with an ARA rotational indexer.

FIGS. 4 through 13 show simplified representations of an example ARA rotational indexer during various stages of wafer placement.

FIGS. 14 through 22 depict simplified representations of an example rotational indexer having a lateral movement mechanism for the first axis during various stages of wafer placement.

FIG. 23 depicts an example single-axis lateral movement mechanism.

FIG. 24 depicts an example dual-axis lateral movement mechanism.

FIG. 25 depicts an example swing-arm movement mechanism.

FIG. 26 depicts a single-axis lateral movement mechanism.

FIG. 27 depicts a side view of an example semiconductor processing tool with a rotational and translational seal mechanism.

FIG. 28 depicts the example semiconductor processing tool of FIG. 27 in a second state of operation.

FIG. 29 depicts an example of a rotational and translational seal mechanism that uses only rotational interfaces in providing the seals.

FIGS. 30 through 33 depict the example rotational and translational seal mechanism of FIG. 29 in various states of operation.

FIG. 34 depicts an example of a simplified rotational and translational seal mechanism.

FIG. 35 depicts a side view of an example semiconductor processing tool featuring a rotational and translational seal mechanism that is similar to that shown in FIG. 30.

FIG. 36 depicts a side view of an example semiconductor processing tool similar to that of FIG. 35 but having a lift capability.

FIG. 37 depicts aside view of another example semiconductor processing tool similar to that of FIG. 35 but having a lift capability.

FIG. 38 depicts an example of a multi-station semiconductor processing tool that is similar to that of FIG. 2, but with the additional inclusion of wafer position sensors.

### DETAILED DESCRIPTION

As discussed above, the present disclosure provides multiple techniques and systems for allowing a rotational indexer to not only index wafers from wafer processing station to wafer processing station within a multi-station semiconductor processing tool, but to also adjust the placement of each individual wafer relative to its destination pedestal so as to be more centered on the destination pedestal. An overview of rotational indexers is provided below to provide context for later discussion of various specific implementations.

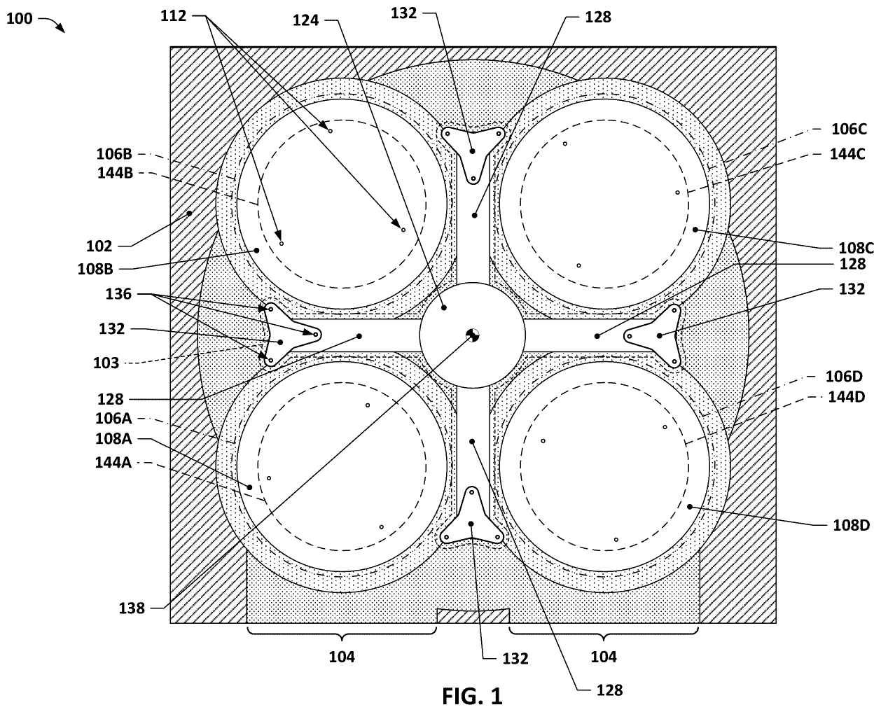

FIG. 1 depicts an example of a multi-station chamber with a rotational indexer system. In FIG. 1, a semiconductor processing tool 100 is shown that includes a chamber 102 that has four wafer processing stations 106 (A-D) within it, each of which has a corresponding pedestal 108 (A-D) which is configured to support a corresponding wafer 144 (A-D). The chamber 102 may, for example, have one or more wafer transfer ports 104 that may be provided to allow wafers 144 to be placed on, or removed from, some of the pedestals 108 by, for example, a wafer handling robot located outside of the chamber 102. The pedestals 108 of the semiconductor processing tool 100 may also include a plurality of lift pins 112 at each wafer processing station 106 that are able to be extended or retracted relative to the corresponding pedestal 108 so as to cause the wafer 144 that may be resting on the corresponding pedestal 108 to be lifted off of, or lowered onto, the underlying pedestal 108.

The semiconductor processing tool 100 may also include a rotational indexer 103, which may have a plurality of indexer arms 128 that have proximal ends that are fixedly connected with a central hub 124 that is configured to rotate about a first axis 138 (the first axis 138 will be understood to be perpendicular to the plane of the page with respect to FIG. 1) and distal ends on which corresponding wafer supports 132 are provided. Each wafer support 132 may, for example, have a plurality of features, such as contact pads 136, that may be designed to stably support one of the wafers 144 from beneath during indexing operations.

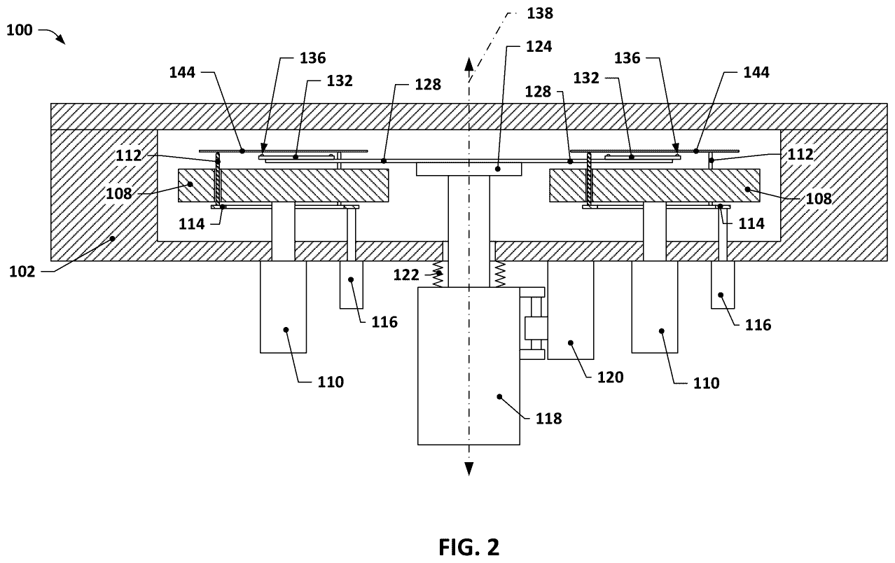

FIG. 2 depicts a diagonal section view of the multi-station chamber of FIG. 1. In FIG. 2, it can be seen that the lift pins 112 may extend through the pedestal, e.g., via through-holes in the pedestal, and may be connected with a lift pin ring 114 that allows the lift pins 112 to be moved up and down relative to the pedestal and in unison responsive to movement of a lift pin actuator 116. The lift pins 112 may generally have uppermost surfaces that are intended to contact the underside of the wafer 144 and support the wafer 144 from below. The lift pins 112 may generally be movable such that those uppermost surfaces can be transitioned between locations that are above and below the uppermost surface of the pedestal 108. Other lift pin mechanisms may be used as well, e.g., independently driven lift pins at each wafer processing station. The lift pins 112 may be actuated so as to lift a wafer 144 that is resting on the top of one of the pedestals 108 clear of that pedestal 108 such that a gap exists between the pedestal 108 and the wafer 144 that is sufficiently large enough that the indexer arms 128 and wafer supports 132 can pass in between the wafers 144 and the pedestals 108. When the wafers 144 are lowered onto the wafer supports 132, they may come to rest on contact pads 136, which may provide support to the wafers 144 with a relatively minimal amount of contact between the wafers 144 and the wafer supports 132.

The rotational indexer 103 may have an indexer drive assembly 118 that may include one or more motors that may be controlled so as to rotate the central hub 124, and thus the indexer arms 128 and the wafer supports 132, about the first axis 138. In some implementations, the indexer drive assembly 118 may also be mounted to a lift actuator 120, in which case a bellows seal 122 may be provided to seal the opening in the chamber 102 through which the central shaft of the rotational indexer 103 may pass. This may allow the indexer arms 128 to be moved up and down as a unit.

During use, the wafers 144 may be raised into elevated positions by the lift pins 112 while the rotational indexer 103 is positioned such that the indexer arms 128 are each interposed between different sets of adjacent pedestals 108. Once the wafers 144 are in the elevated positions, the rotational indexer 103 may be actuated so as to cause the wafer supports 132 to swing into position beneath each wafer 144. When the wafer supports 132 are all positioned underneath a corresponding wafer 144, the lift pins 112 may be retracted and the wafers 144 lowered until they come to rest on the wafer supports 132 positioned beneath the wafers 144. The lift pins 112 may continue to be retracted until they no longer extend into the rotational path of the indexer, thereby allowing the rotational indexer 103 to be rotated about the first axis 138 and the wafers 144 to be transported along arcuate paths from one wafer processing station 106 to another. After the rotational indexer 103 has been actuated so as to cause the wafers 144 to be moved between different wafer processing stations 106, the lift pins 112 may be extended again, lifting the wafers 144 off of the wafer supports 132. Once the wafers 144 are no longer supported by the wafer supports 132, the rotational indexer 103 may be actuated again to rotate the indexer arms 128 so that the wafer supports 132 are no longer beneath the wafers 144. Once the wafer supports 132 are no longer beneath the wafers 144, the lift pins 112 may again be actuated so as to retract them into the pedestals 108, thereby lowering the wafers 144 onto the pedestals 108.

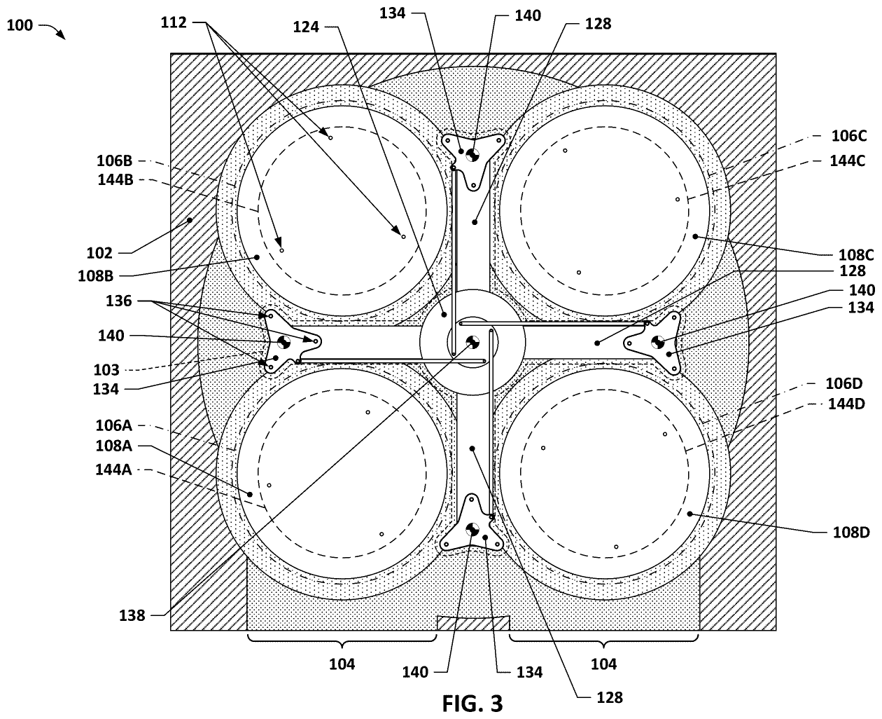

FIG. 3 depicts an example of a multi-station chamber with an ARA rotational indexer. FIG. 3 is substantially identical to FIG. 1 except that the rotational indexer 103′ that is shown is an ARA indexer and has rotatable wafer supports 134 that are each configured to be rotatable relative to the indexer arms 128 about a respective second axis 140. In the depicted example, the ARA indexer #103′ includes a second hub 126 that is able to be independently driven with respect to the central hub 124. The second hub 126, for example, may be connected with a plurality of tie rods 130 that may each be connected at their opposing ends with a corresponding one of the rotatable wafer supports 134 so that when the central hub 124 and the second hub 126 are rotated relative to each other, the rotatable wafer supports 134 undergo similar relative rotation.

The rotational indexer 103′ may be used in generally the same manner as the rotational indexer 103 of FIGS. 1 and 3, but the rotatable wafer supports 134 may also be caused to undergo rotation relative to the indexer arms, thereby allowing their rotational orientation to be adjusted, if desired.

It will be appreciated that both ARA and non-ARA rotational indexers are typically limited in their movement capabilities responsive to various control signals. For example, the positions of the second axes relative to the central hub are not able to be changed responsive to the receipt of a control signal that is caused to be sent by one or more processors of a controller. Similarly, in ARA rotational indexers, no part of the rotatable wafer support is movable relative to the remainder of that rotatable wafer support responsive to the receipt of a control signal that is caused to be sent by one or more processors of the controller.

As discussed earlier, the ARA indexer of FIG. 3 may be reconfigured from the configuration typically used for such indexers so as to have a controller that causes the ARA indexer to adopt an off-center pick paradigm that may be used to allow for each wafer indexed by the ARA indexer to be placed in a position that is specifically tailored to a corresponding pedestal. For example, in a typical ARA indexer, when wafers are transferred from wafer processing station to wafer processing station, the wafers are assumed to each be centered on the pedestals that they are picked up from. Such wafers are also assumed to each be centered on the pedestals that they are placed upon. In other words, the general assumption is that the pedestals are all perfectly placed, e.g., the centers of the pedestals are located along a single perfect circle centered on the first axis and are equally spaced from one another.

It will be understood that references to the “center” of a pedestal in the context of this disclosure is intended to refer to a points in space relative to that pedestal that is coincident with the center axis of a semiconductor wafer placed thereupon when the wafer is considered optimally placed on the pedestal for the purposes of semiconductor processing operations, i.e., the wafer is positioned such that the processing nonuniformities are at a minimum or below a designated threshold. The center of a pedestal may not necessarily exactly coincide with the geometric center of the pedestal. However, most pedestals have one or more co-radial arcuate edges that form the majority of the outer perimeter of the pedestal, and the pedestal center in such examples typically aligns with the center of those arcuate edges.

The reality is that, as with any mechanical system, there will be deviations from the theoretically perfect, and the pedestals within a given multi-station semiconductor processing tool may have center positions that are slightly misaligned from such perfect theoretical locations. The centers of rotation of the rotatable wafer supports relative to the center of rotation of the ARA indexer may also be subject to small variations. In some semiconductor processing tools, the center positions of the pedestals may be measured so as to obtain actual center location information for each pedestal. In such systems, the semiconductor processing tool may be configured, for example, to determine an average positional offset from the theoretical centers of the pedestals for the actual pedestal positions, and the wafers may be placed into the semiconductor processing tool at locations that align the wafer centers with the average offset pedestal center. This may generally act to reduce the maximum placement error that wafers may experience when being moved from station to station through the multi-station semiconductor processing tool but at the expense of increasing the placement error at one or more wafer processing stations within the semiconductor processing tool.

The technique discussed below, however, permits the placement of each individual wafer using an ARA indexer to be fine-tuned to adjust for potential deviations of the centers of the pedestals from theoretically perfect pedestal center locations.

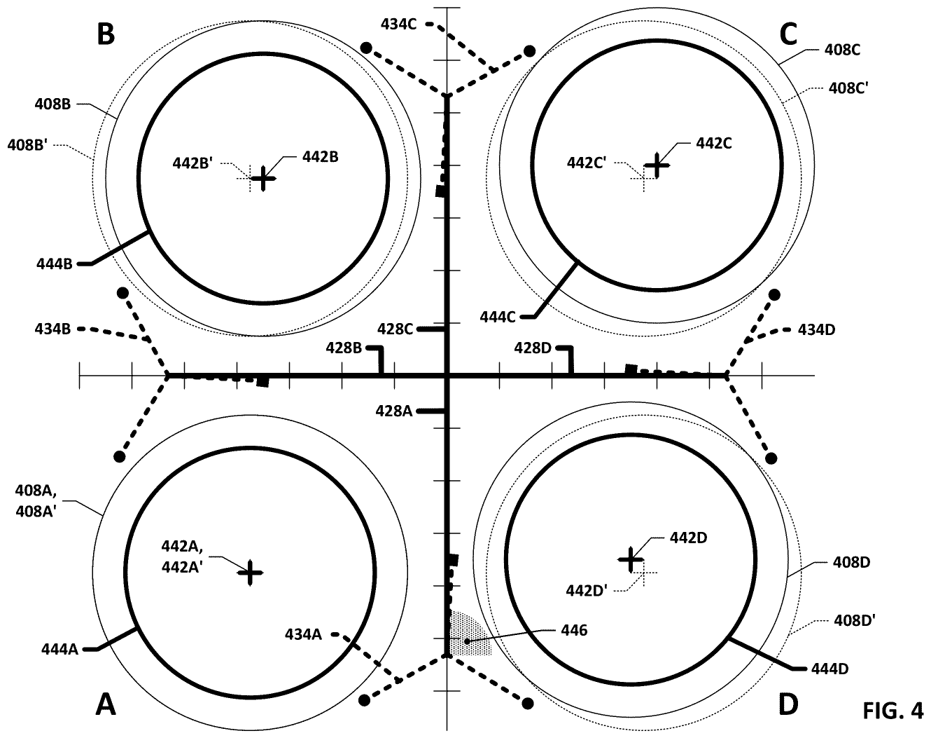

To assist in this discussion, FIGS. 4 through 13 are provided that show simplified representations of an example ARA rotational indexer during various stages of wafer placement. The chamber, lift pins, central hub, second hub, tie rods, etc., are omitted from these Figures, and indexer arms 428 and rotatable wafer supports 434 are represented simply by thick lines (the indexer arms 428 are represented by thick solid lines, and the rotatable wafer supports 434 are represented by thick dotted lines). The rotatable wafer supports 434 in these Figures are each in the form of a triad of fingers that radiate outward from a common center point at the distal end of one of the indexer arms 428 that is also the center of rotation of that rotatable wafer support 434 relative to that indexer arm 428; the second axes about which each rotatable wafer support 434 rotates each intersect with their respective common center points. In order to assist with identifying the various rotational orientations of the rotatable wafer supports 434 in FIGS. 4 through 13, the same fingers in the rotatable wafer supports 434 terminate in a square symbol whereas the other two fingers in each rotatable wafer support 434 terminate in a round symbol.

In this example, the rotatable wafer supports 434 are able to be rotated in unison relative to the indexer arms 428 through a sweep angle 446 of 900 (shown only for one rotatable wafer support 434, but applicable to all four depicted rotatable wafer supports 434), although other sweep angles may be used for other implementations, depending on the particular geometry used. The sweep angle 446 that is shown is defined such that the finger of the rotatable wafer support 434A that terminates in a square symbol is always within the sweep angle 446. It will also be appreciated that while this example features a rotational indexer with 4 indexer arms, other implementations may use a larger or smaller plurality of indexer arms, e.g., 3 indexer arms, 5 indexer arms, or 6 indexer arms.

The indexer arms 428 may have proximal ends that are fixedly connected with a central hub (not shown, but see FIGS. 1 through 2 discussed above) that is rotatable about the center of the array of indexer arms 428, i.e., about a first axis (not explicitly depicted, but located at the center of the indexer arms 428). There are various elements in FIGS. 4 through 13 that appear multiple, i.e., four, times within each Figure. To assist with differentiating between different, but identical-looking, instances of such elements, the callouts for these elements may have an A, B, C, or D appended thereto, although it will be understood that reference to the root callout for such elements absent such an appended A, B, C, or D is intended to refer to all of such elements that are depicted.

As can be seen in FIG. 4, there are four pedestals 408 that are shown, each being positioned in a different quadrant A, B, C. or D. The quadrants are simply provided to facilitate interpretation of the Figures and does not represent structures that would actually be present. The quadrants are based on a rectangular coordinate system that is centered on the first axis.

The pedestals 408 are shown in solid lines, but there are also pedestals 408′ that are shown in dotted lines that represent theoretically perfectly placed pedestals, e.g., pedestals that are all positioned with their center points lying exactly on the same circle that is, itself, centered on the first axis and being located at positions on that circle that are exactly equally spaced apart along the circle. As can be seen, the pedestal 408A is actually perfectly placed, and the solid line circle representing the pedestal 408A thus masks the dotted line circle representing the “perfect” pedestal position 408A′. In contrast, each of the pedestals 408B, 408C, and 408D is positioned somewhat off-center from the respective “perfect” pedestal positions 408B′, 408C′, and 408D′. It will be understood that the magnitude of such misalignments in FIGS. 4 through 13 is deliberately exaggerated so as to more clearly convey the concepts discussed herein. In actual practice, the amount of such misalignment is more likely on the order of less than a millimeter, e.g., on the order of tens or hundreds of microns, for a system that processes 300 mm diameter wafers (other, although generally similar, magnitudes of misalignment may be present in systems that process other sizes of wafers, e.g., 200 mm or 450 mm diameter wafers). Similarly, the rotational movements discussed below will also be recognized to likely be quite exaggerated, while in actual practice such movements may actually be quite small in nature.

Also shown in FIG. 4 are target locations 442, which coincide with the center points of the pedestals 408. Target locations 442′ similarly coincide with the center points of the “perfect” pedestal positions 408B′, 408C′, and 408D′; as can be seen, the pedestals 408B, 408C, and 408D are each offset from the “perfect” pedestal positions 408B′, 408C′, and 408D′ in different directions and to different degrees.

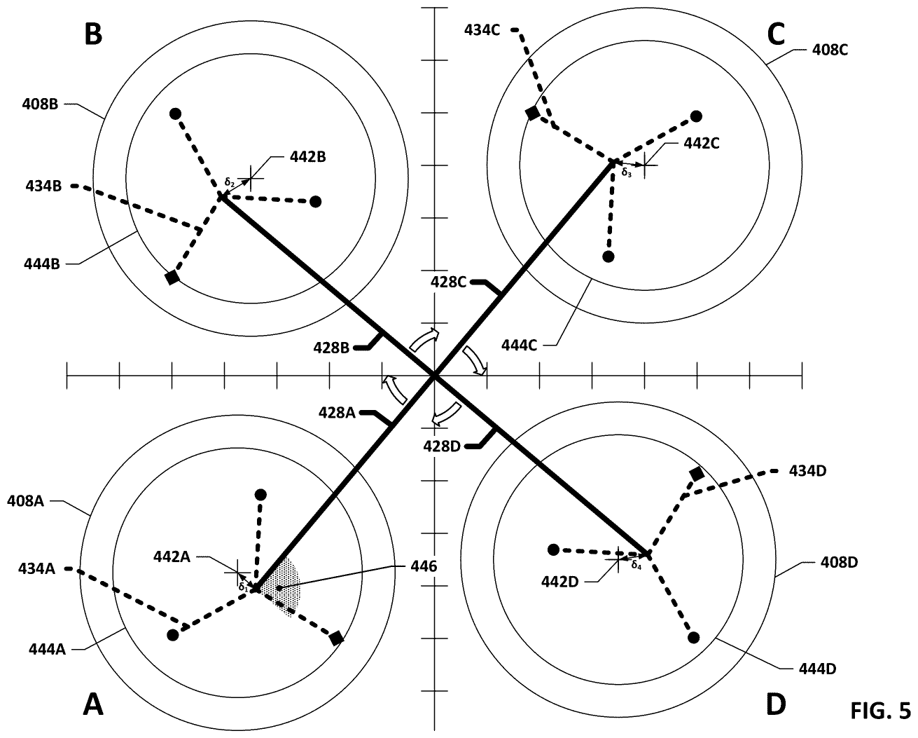

For clarity, FIGS. 5 through 13 omit the “perfect” pedestal locations 408′ and target locations 442′, although the pedestals 408 and target locations 442 shown in FIG. 4 are retained in each of FIGS. 5 through 13.

In FIG. 4, the rotational indexer is “parked” in a position in which each indexer arm 428 is located midway between two adjacent wafer processing stations, e.g., between A and B, B and C, C and D, or D and A. Such a configuration may be used when processing operations are being performed on wafers 444, which are each shown as being centered on the respective pedestals 408 that support them. The wafers 444 are shown in heavy weight solid lines in FIGS. 4 through 13 when not being supported by the ARA indexer and lighter weight solid lines when being supported thereby. The indexer arms 428 are, in this configuration, positioned so as to be as far as possible from each pedestal 408 so as to minimize the potential effects that the indexer arms 428 may have on the processing operations that are being performed at each wafer processing station. When such wafer processing operations are complete, the wafers 444 may be lifted clear of the pedestals 408 by, for example, lift pins (see earlier discussion and Figures).

In FIG. 5, the rotational indexer has been rotated an amount that is sufficient to position each of the rotatable wafer supports 434 underneath a corresponding one of the wafers 444 while at the same time avoiding positioning of the rotatable wafer supports 434 such that any of the second axes about which each rotatable wafer support 434 is able to rotate relative to the indexer arms 428 are aligned with the target locations 442 of the pedestals 408. Thus, the second axes of the rotatable wafer supports 434A, 434B, 434C, and 434D are each positioned, respectively, distances of δ₁, δ₂, δ₃, and δ₄ from the corresponding target locations 442A, 442B, 442C, and 442D. If the pedestals 408A, 408B, 408C, and 408D are all perfectly placed relative to the first axis of the rotational indexer, then δ₁, δ₂, δ₃, and δ₄ will all be the same. However, δ₁, δ₂, δ₃, and δ₄ may not all be the same if there is any deviation in the placement of the pedestals 408 from the ideal positioning.

As can also be seen in FIG. 5, the rotatable wafer supports 434 have also been rotated about their respective second axes relative to the indexer arms 428, although this is optional. Generally speaking, the rotational indexer may be caused to rotate about the first axis by an amount that positions the rotatable wafer supports 434 sufficiently close to the target locations 442 that wafers 444 that are centered on the target locations 442 but held aloft by lift pins or other structures over the target locations 442 are then able to be lowered onto the rotatable wafer supports 434 and supported by the rotatable wafer supports 434 without falling off of the rotatable wafer supports. For example, if the rotatable wafer supports 434 each have three contact pads that are designed to support a wafer 444 placed upon the rotatable wafer supports 434, then the rotational indexer may at least be rotated far enough that, when viewed from along a direction parallel to the first axis, the target location 442 of each pedestal 408 is located within the bounds of a corresponding reference triangle having vertices that align with the contact pads of a corresponding one of the rotatable wafer supports.

Once the rotational indexer has been rotated, e.g., to a position as shown in FIG. 5, the wafers 444 may be lowered onto the rotatable wafer supports 434. It will be appreciated that the centers of the wafers 444, if aligned with the target locations 442, will be laterally offset from the second axes of the rotatable wafer supports 434 after such placement. It will be appreciated that for each wafer transfer operation there will be a reference point associated with each rotatable wafer support 434 that is fixed with respect to that rotatable wafer support 434 and that coincides with the estimated center of the wafer that is placed on that rotatable wafer support 434. The reference point for any given rotatable wafer support 434 may thus be assumed to potentially change with each placement of a wafer onto such a rotatable wafer support 434, depending on where the estimated center of the wafer is relative to the rotatable wafer support 434. If the actual wafer positions are not known at the time the wafers are placed on the rotatable wafer supports 434, then the estimated centers of the wafers may, for example, be assumed to be directly over the target locations 442, i.e., the target locations 442 may be used as proxies for the estimated centers of the wafers 444 (which is a reasonable assumption if the wafers 444 are individually centered on each pedestal 408). In some implementations, however, the semiconductor processing tool in question may have sensors that are able to detect, in situ, the locations of each of the wafers 444 within the tool and may thus obtain location information on the actual locations of the centers of each of the wafers 444. In such implementations, the measured wafer center locations may be used as the locations of the estimated centers of the wafers 444, and the reference point for each rotatable wafer support 434 may be selected so as to coincide with the measured center location of the wafer 444 supported by that rotatable wafer support 434.

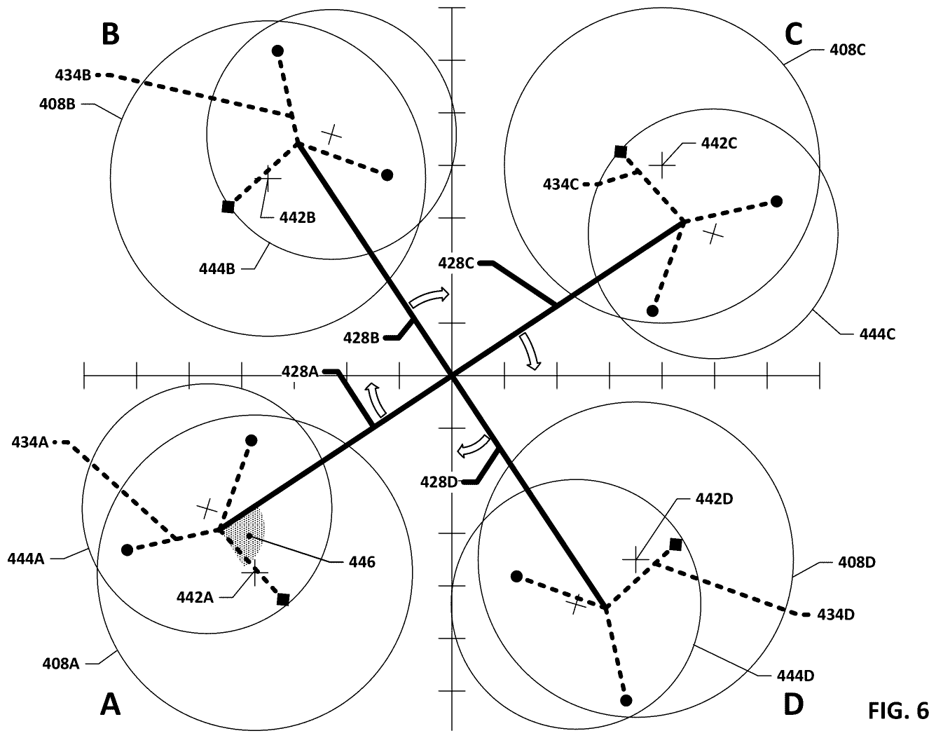

Once the wafers 444 are placed on the rotatable wafer supports 434, then the rotational indexer may be caused to continue to rotate, thereby advancing each wafer 444 from its embarkation pedestal 408 to a destination pedestal 408 at the next wafer processing station; this is shown in FIG. 6 (which shows the rotational indexer with the wafers 444 in transit to the next wafer processing station). For clarity, during such wafer transfer operations, each wafer transfer may involve a selected embarkation pedestal (the pedestal 408 from which a given wafer 444 is transferred), a selected destination pedestal (the pedestal 408 to which the given wafer 444 is transferred), and a selected rotatable wafer support (the rotatable wafer support 434 that supports the wafer 444 during the transfer operation). It will be appreciated that a given pedestal 408 may be a destination pedestal with respect to one wafer but may also be an embarkation pedestal with respect to another wafer for a given rotation of the rotational indexer. In some implementations, an in-place rotation may be performed without transferring the wafer between stations, i.e., the embarkation pedestal and the destination pedestal may be selected to be the same pedestal. In such implementations, the off-center pick paradigm described herein may still be used in order to ensure that the wafer, when re-placed on the same pedestal, is still centered on that pedestal.

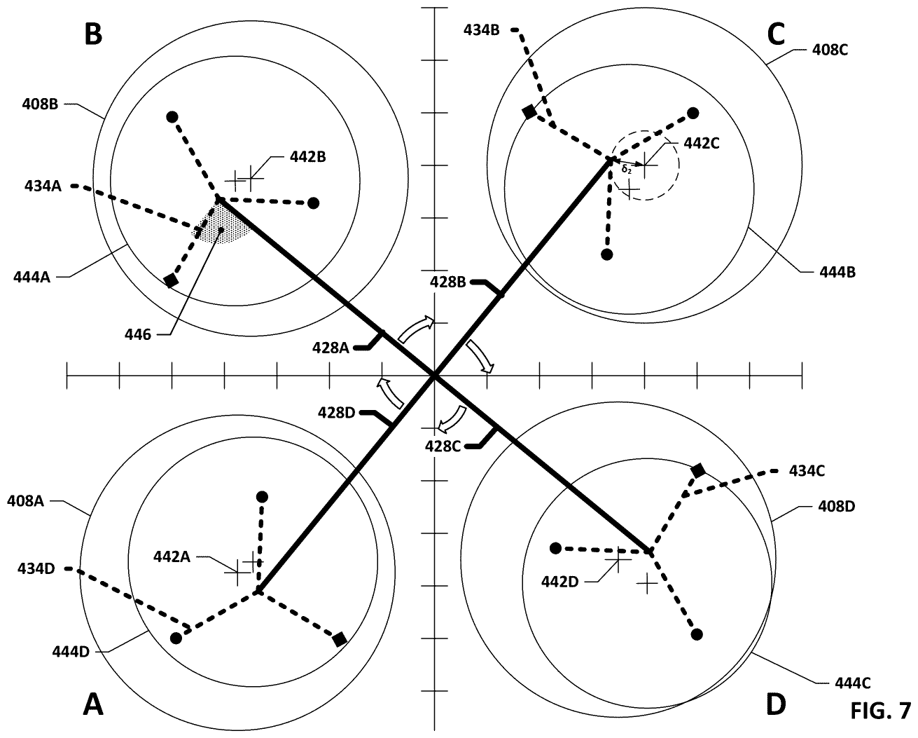

In FIG. 7, the rotational indexer has been rotated such that each wafer 444 is now positioned above one of the pedestals 408. As can be seen, the rotational indexer's angular position is such that the second axis of the rotatable wafer support 434B is positioned a distance δ₂ from the target location 442C of the pedestal 408C (the dashed circle around the target location 442C is a circle with a radius of δ₂). This distance δ₂ represents the distance that the reference point for the rotatable wafer support 434B (which is coincident with the estimated center of the wafer 444B) is from the second axis for the rotatable wafer support 434B. Generally speaking, there are usually two potential angular positions of the rotational indexer that result in the reference point for the rotatable wafer support 434B being a distance δ₂ from the target location 442C—the indicated position and one in which the indexer arm 428B is on the other side of an axis extending between the first axis and the target location 442C (there are some scenarios in which this is not the case, e.g., if the vector along which δ₂ extends intersects with the first axis). The particular angular position for the rotational indexer that is chosen for a given wafer placement operation may be selected so as to minimize the amount of rotation of the rotatable wafer support 434 that is needed in order to center the wafer (one of the two angular placements will typically require more of such rotation than the other).

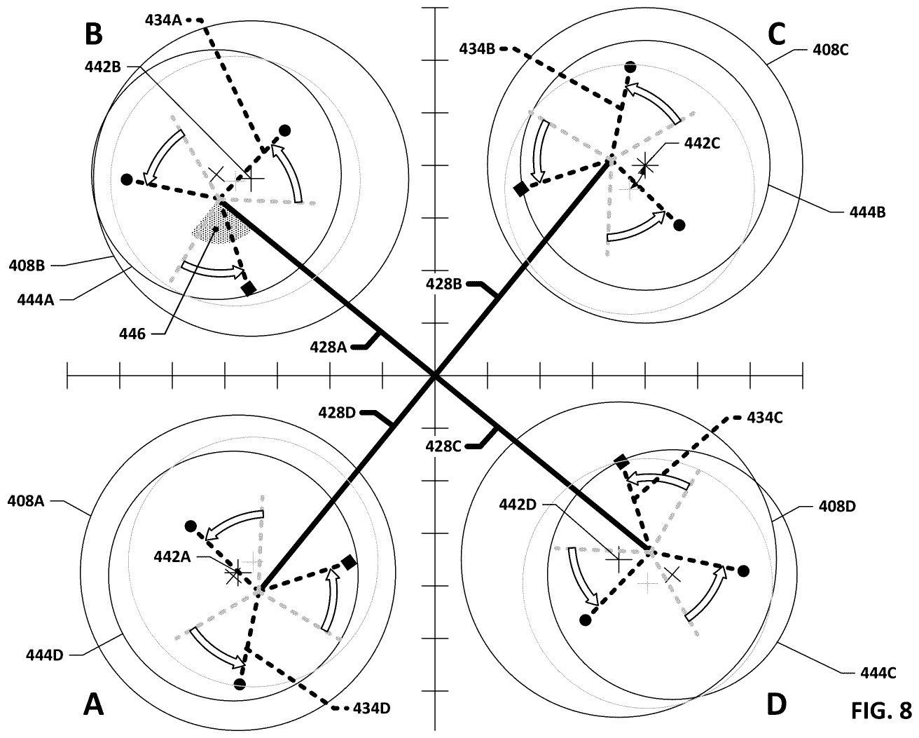

In FIG. 8, the rotatable wafer supports 434 have been rotated relative to the indexer arms 428 so that the reference point for the rotatable wafer support 434B is directly over the target location 442C. As can be seen, this rotation serves to position the wafer 444B so that it is centered on the pedestal 408C (also visible in FIG. 8 are greyed-out positions of each wafer 444 and rotatable wafer support 434 that indicate their positioning prior to such rotation).

It will be appreciated that while the rotations of the rotational indexer and the rotatable wafer supports 434 are shown as separate operations, with the rotational indexer shown as rotating while supporting the wafers 444 in FIGS. 6 and 7 and the rotatable wafer supports 434 shown as rotating while supporting the wafers 444 in FIG. 8, such rotations may also occur in tandem, e.g., the rotatable wafer supports 434 may be caused to rotate relative to the indexer arms 428 about their respective second axes while the indexer arms 428 are caused to rotate about the first axis. It will be further appreciated that the amounts of rotation of the indexer arms 428 about the first axis and the rotatable wafer supports 434 relative to the indexer arms 428 and about the second axes that are needed in order to position the reference point for the rotatable wafer support 434B directly over the target location 442C may be determined using, for example, inverse kinematics techniques.

It will also be appreciated that the various target locations, estimated wafer centers, and reference points discussed herein may generally be thought of as two-dimensional locations that lie in a common plane, e.g., projections of such points onto a plane perpendicular to the rotational axis of the indexer, and that discussion of distances or alignments between such locations is intended to refer to distances or alignments of such points within such a planar context.

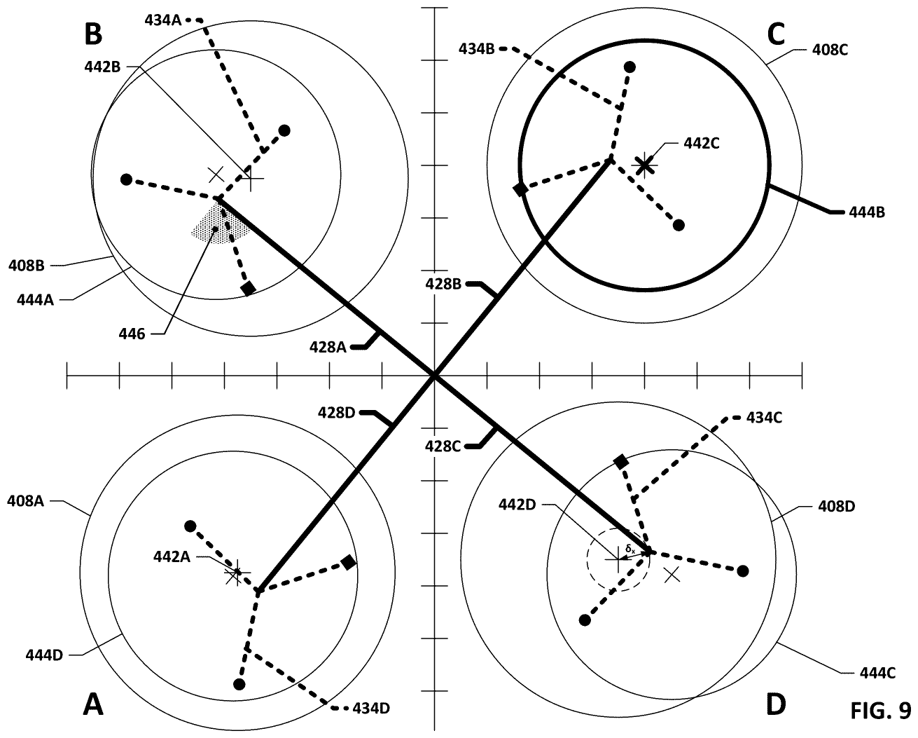

In FIG. 9, the wafer 444B has been lifted off of the rotatable wafer support 434B by lift pins associated with the pedestal 408C. As a result, the wafer 444B will no longer move or rotate when the rotational indexer and/or rotatable wafer supports 434 move or rotate during the remainder of the wafer transfer operation. This stationary aspect of the wafer 444B is represented by the use of a thick line to represent the wafer 444B.

With the placement of the wafer 444B, the focus may now shift to centering and placing another of the wafers 444. In FIG. 9, the wafer 444C is now the wafer of interest. For the wafer 444C, the selected embarkation pedestal 408 is the pedestal 408C, the selected destination pedestal is the pedestal 408D, and the selected rotatable wafer support is the rotatable wafer support 434C. The distance between the reference point for the rotatable wafer support 434C and the second axis for the rotatable wafer support 434C is δ₃ (see FIG. 5). The dashed circle around the target location 442C has a radius of δ₃. In FIG. 9, the second axis of the rotatable wafer support 434C is a distance δₓ from the target location 442D. As it happens, the distance δₓ turns out to be nearly the same as the distance δ₃ in this example, although depending on the various relative positions of the pedestals, this may often not be the case.

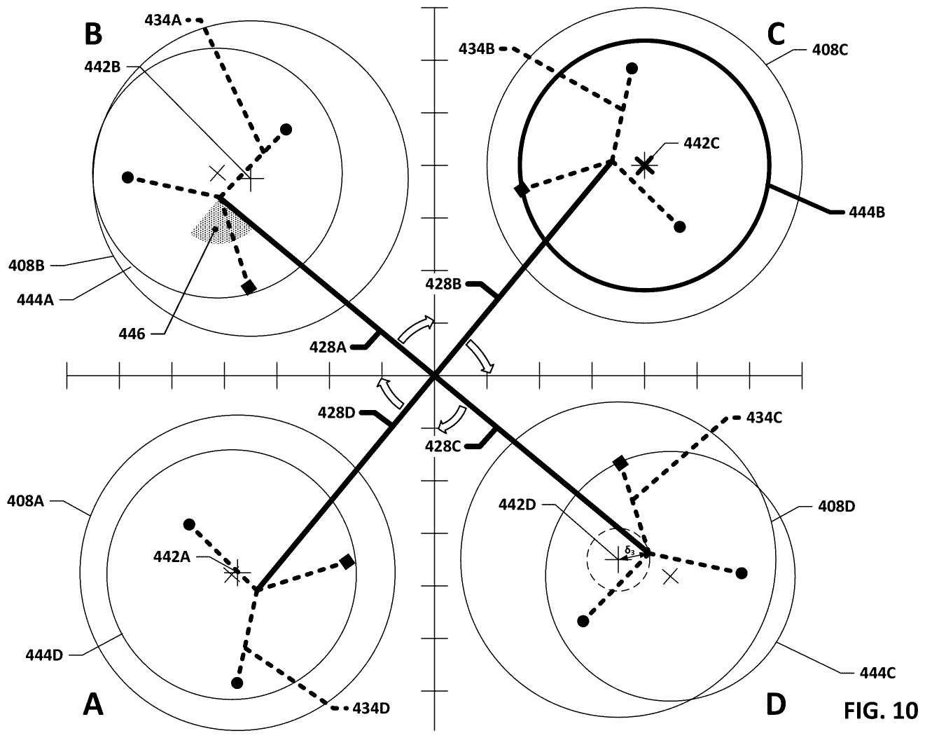

In FIG. 10, the rotational indexer has been rotated about the first axis by a small amount sufficient to position the second axis of the rotatable wafer support 434C such that it is a distance δ₃ away from the target location 442D.

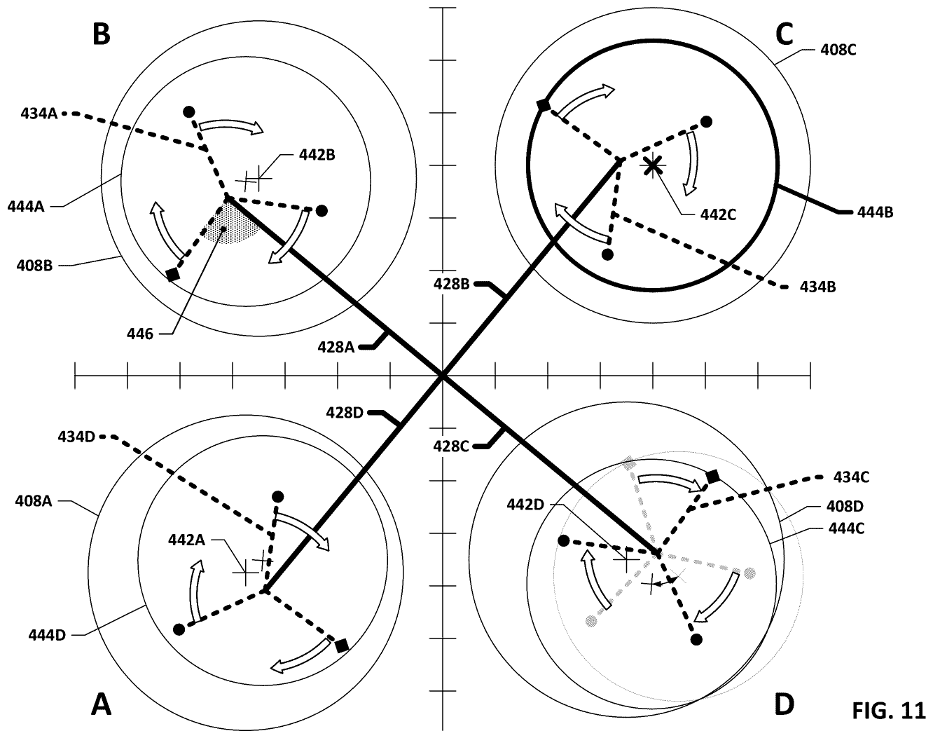

In FIG. 11, the rotatable wafer supports 434 have been caused to rotate about their second axes relative to the indexer arms 428. In this particular scenario, the amount of rotational movement of the rotatable wafer supports 434 relative to the indexer arms 428 may not be sufficient to allow the reference point for the rotatable wafer support 434 to be positioned over the target location 442D in one rotation operation. For example, as can be seen with respect to the sweep angle 446 shown for the rotatable wafer support 434A, further clockwise rotation of the rotatable wafer supports 434 relative to the indexer arms 428 is not possible for this particular example mechanism.

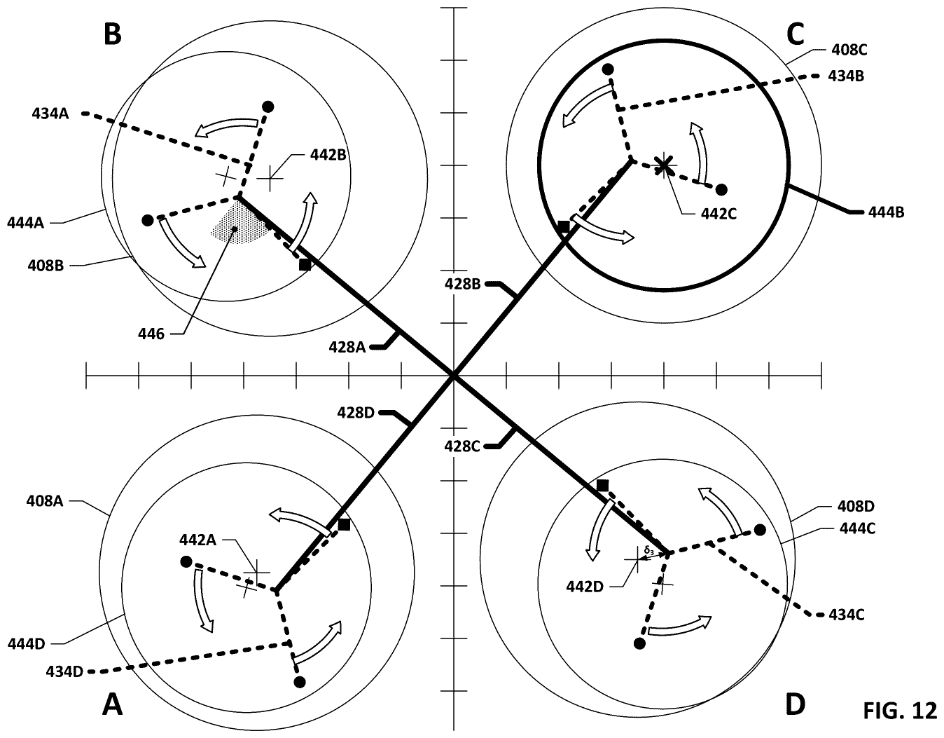

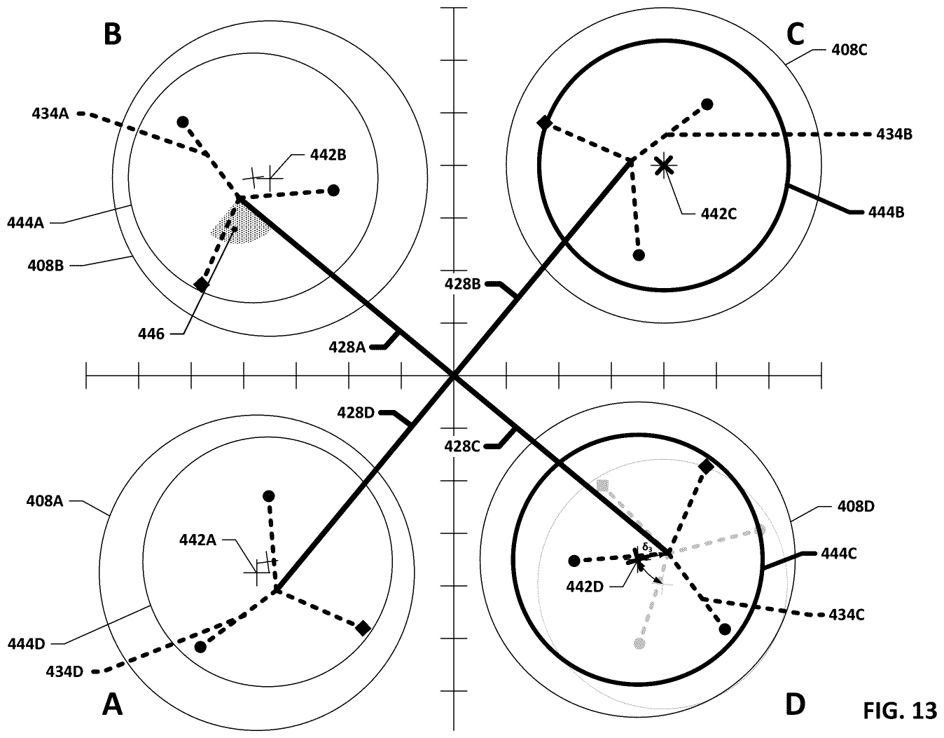

In such instances, a multi-stage rotation may be performed for the wafer in question, as shown in FIGS. 12 and 13. In FIG. 12, the wafer 444C has been temporarily lifted off of the rotatable wafer support 434C, e.g., using lift pins for the pedestal 408D (as indicated by the heavy weight solid line used to show the wafer 444C). After the wafer 444C is no longer supported by the rotatable wafer support 434C, the rotatable wafer supports 434 may be cause to rotate relative to the indexer arms 428 about their respective second axes in the opposite direction from the rotations they underwent relative to the indexer arms 428 immediately prior to the removal of the wafer 444C from the rotatable wafer support #A34C. In this example, such rotation is in a counterclockwise manner compared with the clockwise rotation shown in FIG. 11. This counter-rotation may serve to reset the positioning of the rotatable wafer support 434C within the sweep angle 446 such that a subsequent further clockwise rotation of the rotatable wafer support 434C may be performed.

In FIG. 13, the wafer 444C has been lowered back onto the rotatable wafer support 434C and is then rotated relative to the indexer arms 428 by a further clockwise amount that is sufficient to align the reference point for the rotatable wafer support 434C over the target location 442D. With the wafer 444C centered on the target location 442D, the wafer 444C may be lifted off of the rotatable wafer support 434C by the lift pins again, as indicated by the use of heavy weight line font.

Similar placement and centering operations may be performed for the remaining wafers 444, e.g., the wafers 444A and 444D. It will be appreciated that from a practical perspective, the above technique will generally involve at least some sequential placement of the wafers 444 at each destination pedestal unless the target locations and estimated centers of the wafers are both arranged in perfect circular patterns about the first axis (which is an unlikely occurrence in actual practice). Since the indexer arms of a rotational indexer rotate in unison and the rotatable wafer supports in an ARA indexer are configured to rotate relative to the indexer arms in unison, any angular movements made by the indexer arms and/or the rotatable wafer supports relative to the indexer arms to center a particular wafer on the target location of a given destination pedestal will typically be different from the angular movements made by the indexer arms and/or the rotatable wafer supports relative to the indexer arms to center a different wafer on the target location of a different destination pedestal. As a result, the centering operations performed above may generally be performed separately, e.g., sequentially, for each wafer during a given multi-wafer transfer operation.

It will be further appreciated that while the example discussed above shows the wafers being retrieved from their respective embarkation pedestals in one operation and then placed on their respective destination pedestals in separate operations with rotational adjustments made, as necessary, in between each such placement operation in order to center the wafers on the respective target locations of the destination pedestals, the same general technique may also be practiced “in reverse,” so to speak. For example, each wafer may instead initially be placed on each rotatable wafer support such that the estimated centers of all of the wafers can be simultaneously positioned over all of the respective target locations on the destination pedestals. In such an implementation, the wafers may then all be lifted off of the rotatable wafer supports by lift pins simultaneously once centered over the destination pedestal target locations. The initial placement of the wafers on the rotatable wafer supports in such an implementation, however, may be performed sequentially so as to allow the individual placement of each wafer on its respective rotatable wafer support to be adjusted so as to align the estimated center of the wafer with a reference point that is fixed with respect to that rotatable wafer support and that is also able to be positioned over the target location of the destination pedestal simultaneously with the reference points that are fixed with respect to the other rotatable wafer supports.

Thus, it will generally be the case that there will be some non-simultaneous wafer placement on the rotatable wafer supports and/or non-simultaneous wafer removal from the rotatable wafer supports during a given wafer transfer operation per the discussion above. As a result, such techniques may incur a slight throughput penalty since the overall transfer operation may take longer to complete due to the non-simultaneous wafer placement and/or retrieval operations. However, the increased accuracy with which wafers may be centered at each destination pedestal may offset that throughput penalty by providing for more accurate centering, thereby increasing the uniformity of wafer processing operations that are performed on such wafers.

It will be further appreciated that in some implementations, wafers other than the wafer presently being centered may be temporarily removed from their rotatable wafer supports during centering of a wafer. For example, in the figures discussed above, each wafer was removed from the rotational indexer after being centered at its respective destination pedestal (e.g., placed on lift pins at the destination pedestal), thereby preventing the centered wafer from being subjected to further movement by the rotational indexer during the centering of other wafers which would cause the centered wafer to no longer be centered on its respective destination pedestal. Wafers that have not yet been centered may, however, also be temporarily placed on the lift pins of their respective destination pedestals while another wafer is being centered. In such implementations, the wafers may all be transported simultaneously by the rotational indexer between wafer processing stations but may then be individually supported by the rotational indexer during smaller-magnitude motions that may be used to individually center the wafers on their respective pedestals. This may reduce the risk of potential wafer slippage relative to the rotatable wafer supports. For example, a rotational movement of the selected rotatable wafer support needed to center the wafer supported thereby will result in a similar rotational movement of the other rotatable wafer supports as well. If wafers are carried by those other rotatable wafer supports, then this may potentially increase the risk that those other wafers may slip relative to the rotatable wafer supports that support them. In particular, differing δ distances between the estimated center locations of each wafer and the second axes of the rotatable wafer supports that support the wafers may result in differences in the maximum rotational speed that each rotatable wafer support may be rotated at before the wafer supported thereby starts to slip. Temporarily placing the uncentered wafers that are not actively being centered on lift pins may thus allow the selected rotatable wafer support to be rotated at a speed that is tailored to the S distance between the estimated center location of the wafer supported thereby and the second axis of the selected rotatable wafer support without concern for whether that same rotational speed might cause slippage in other wafers being supported by the rotational indexer.

It will be further appreciated that in some such implementations, the rotational indexer and rotatable wafer supports may be placed in a particular configuration prior to temporarily transferring the wafers not being centered to their respective lift pins. Before each wafer is placed back upon the rotational indexer in preparation for centering, the rotational indexer and rotatable wafer supports may again be placed in that particular configuration so that each wafer has the same positioning and orientation vis-a-vis the rotatable wafer support that it is placed on as that wafer had before it was removed from that same rotatable wafer support.

While there is flexibility in terms of the magnitude of the offset distance between the estimated wafer centers and the second axes that is used in the above-discussed techniques, in some implementations, the offset distance may be set to be larger than twice the estimated maximum pedestal location tolerance within the chamber of the multi-station semiconductor processing tool. At the same time, and as mentioned previously, the offset distance may generally also be selected so as to avoid situations in which the estimated center of a wafer may be located outside of, for example, a triangular region defined by three points of contact between the wafer and the rotatable wafer support that is used to support the wafer (it will be understood that this may depend, for example, on the particular orientation of the rotatable wafer support relative to the wafer).

As discussed earlier, the above techniques may be used with ARA rotational indexers without necessarily requiring any additional hardware (unless, for example, in-situ wafer position sensing is used to determine the locations of the estimated centers of the wafers, in which case some sort of wafer position sensor system would be needed that is not typically included in systems that use ARA rotational indexers). Such techniques may, for example, be taken advantage of by specially configuring the controller that controls movement of such an ARA indexer with computer-executable instructions for performing wafer transfer operations per such techniques.

As also discussed earlier, however, a similar technique was also conceived of in which the indexer system incorporated additional components that facilitated the introduction of a controllable lateral offset between the first axis of the indexer and the pedestals on which the indexer may be configured to place wafers. Thus, the shaft(s) of the rotational indexer that is/are centered on the first axis are able to not only rotate to rotate the indexer hub and arms to effect wafer transfers from pedestal to pedestal of the wafer processing stations, but may also be laterally translated in one or more directions perpendicular to the first axis to facilitate fine-tuning the placement of each wafer on the respective destination pedestal. Both ARA and non-ARA indexers may be equipped with such components, thereby allowing either type of indexer to fine-tune the placement of wafers relative to the pedestals within the tool during indexing operations. In contrast, the technique discussed earlier with respect to FIGS. 4 through 13 can only be implemented using ARA indexers.

Any of a variety of mechanisms may be used to laterally translate the first axis of the rotational indexer; the amount of translation that is typically provided by such systems may actually be quite small, e.g., on the order of magnitude of the amount of potential positioning correction that may need to be performed in order to account for wafer slippage and/or pedestal position error. For example, in some implementations, the base of the rotational indexer may be mounted to a linear actuator and guide system that allows the base of the rotational indexer to be moved back and forth along a single axis by a small amount. In another implementation, the base of the rotational indexer may be mounted to a rotational pivot that is offset from, but parallel to, the first axis, and a linear actuator or other type of actuator may be coupled to the base and configured to apply a torque to the base about the rotational pivot, thereby causing the base to rotate about the rotational pivot. As part of that rotation, the first axis may be caused to travel along a circular path, which may involve translation of the first axis along two axes.

A potential challenge to such first-axis offset systems is that the interface between the rotating shaft(s) of the indexer drive system and the chamber housing of the multi-station semiconductor processing tool must, in many cases, be sealed so as to allow the interior volume of the chamber housing, where the wafer processing operations occur, to be held at vacuum or partial vacuum relative to the environment outside of the interior volume of the chamber housing. Such a seal must be able to accommodate both rotational motion, e.g., between the shaft or shafts that drive the rotation of the rotational indexer (and, if present, the rotatable wafer supports thereof) and the chamber housing and a small amount of lateral motion between that shaft or shafts and the chamber housing, i.e., in a direction perpendicular to the axis of rotation of the shafts relative to the chamber housing.

One such seal arrangement may utilize a combination of a metal bellows seal and a rotational seal, such as a ferrofluidic seal. Metal bellows seals are typically used to allow for axial movement between two components and provide a thin-wall accordion-fold structure that is able to change length to accommodate changes in distance between the two ends of the metal bellows seal. In the context of rotational indexers that have an actuation system that allows the first axis of the rotational indexer to be shifted laterally, such a metal bellows seal may also or alternatively be used to accommodate the small amount of lateral movement that the first axis may undergo during operation. The amount of such lateral movement that may be accommodated by such a bellows seal in such a configuration may be quite small, e.g., on the order of tens or hundreds of microns or less than one to several, e.g., 2, 3, 4, 5, 7, 8, 9 or 10 millimeters.

Ferrofluidic seals, such as those offered by Ferrotec (USA) Corporation, are a particular type of rotational seal in which a magnetic field is developed across a small radial gap between two components (one of which may be a shaft or similar rotational element) that rotate relative to each other, e.g., a shaft and a bearing unit. A ferrofluid is suspended within the radial gap by the magnetic field and forms, in effect, a liquid O-ring that seals the radial gap. In many ferrofluidic seals, there may be multiple such liquid O-rings that are created in series along the axis of the shaft due to the geometry of the shaft. Such multiple liquid O-rings may be arranged in series, allowing for the total pressure differential to be distributed between the different O-rings and allowing the ferrofluidic seal to seal against pressure differentials that are much higher than the differential that can be sealed with a single liquid O-ring seal. Ferrofluidic seals also typically include rotational bearing units, e.g., ball bearings, that act to structurally support the shaft relative to the magnetized, non-ferrofluidic components that encircle it and maintain the radial gap between the shaft and the magnetized, non-ferrofluidic components constant to ensure that the liquid O-rings remain symmetric.

Another such seal arrangement may utilize multiple ferrofluidic seals to accommodate the lateral movement of the first axis. In such an arrangement, the ferrofluidic seals may be arranged in an eccentric manner, e.g., with the rotational axes of the ferrofluidic seals offset from one another. In such implementations, depending on the nature of the lateral movement actuation system, two or three such non-concentric ferrofluidic seals may be used, with the rotational axes of each being offset from the rotational axis of the adjacent ferrofluidic seal or seals in a direction or directions perpendicular to those rotational axes.

In such systems, the eccentrically mounted ferrofluidic seals may rotate relative to each other to accommodate the limited lateral movement of the first axis of the rotational indexer relative to the chamber housing that may be used for wafer centering adjustment. Such rotation may be driven entirely by an actuation system that imparts lateral force directly to the indexer drive assembly, with the eccentrically mounted ferrofluidic seals being passively driven by such movement, or by an actuation system that imparts at least some force or torsion directly to one or more of the ferrofluidic seals (or to components that are fixed with respect thereto).

It will be recognized that any of a wide variety of mechanisms may be used to impart lateral motion to the first axis relative to the chamber housing, and that the selection of any particular one of such mechanisms may be made, as appropriate, from a wide variety of options that may be available, including, for example, systems in which the lateral motion mechanism is a single-axis translation mechanism, a dual-axis translation mechanism, a single-axis translation mechanism coupled with a rotational mount to allow re-orientation of the translation axis, or a swing-arm translation system.

As noted earlier, systems that use eccentrically mounted ferrofluidic seals may include at least two or three eccentrically mounted ferrofluidic seals. For lateral movement mechanisms in which motion of the indexer drive assembly is not constrained to only translational movement of the indexer drive assembly relative to the chamber housing, e.g., mechanisms in which the indexer drive assembly is also caused to rotate slightly relative to the chamber housing, or in which the lateral movement mechanism is capable of biaxial lateral translation, e.g., mechanisms featuring an XY translation stage, two eccentrically mounted ferrofluidic seals may be used in some cases to accommodate the lateral translational movement discussed above. For lateral movement mechanisms in which motion of the indexer drive assembly is constrained to only single-axis translational movement of the indexer drive assembly relative to the chamber housing, three eccentrically mounted ferrofluidic seals may be used to accommodate the lateral translation movement discussed above.

It will also be understood that other types of rotational seals that are able to effectively seal between vacuum and atmospheric environments may also be used in place of one or more of the ferrofluidic seals, if desired. Ferrofluidic seals, however, are thought to provide the most reliable and high-performance vacuum-capable seals and may thus provide for a more effective sealing solution if used.

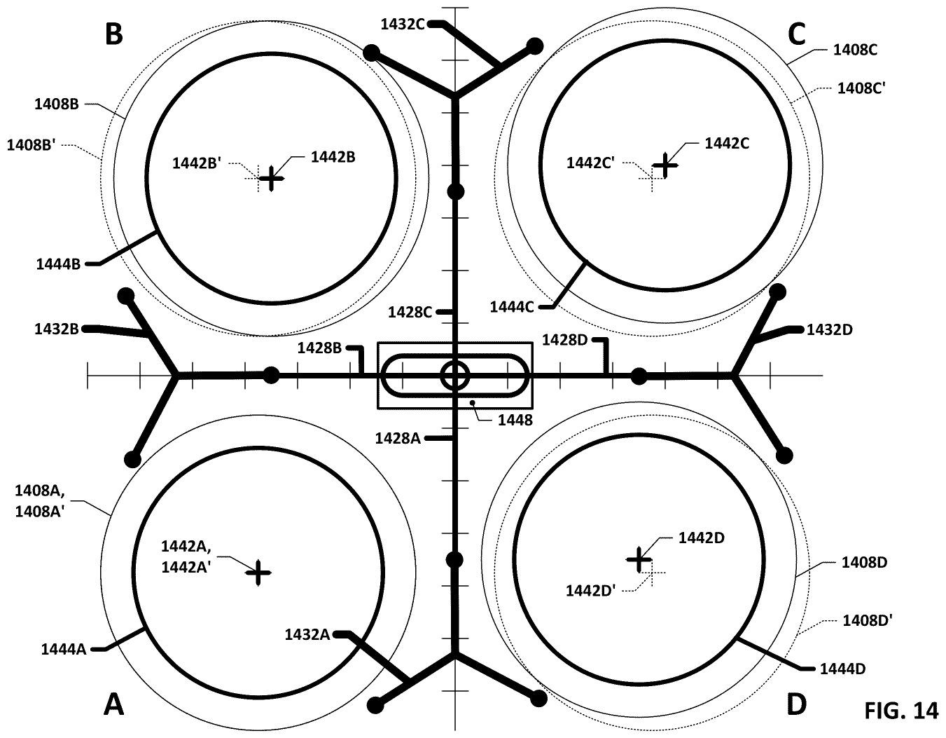

FIGS. 14 through 22 depict, in a manner similar to FIGS. 4 through 13, the use of a rotational indexer equipped with a lateral movement mechanism that allows the first axis of the rotational indexer to be moved in one or more lateral directions, i.e., in a direction or directions parallel to the plane of the Figure, to facilitate wafer-by-wafer centering during wafer transfers during various stages of operation.

The simplified representation of an example rotational indexer in FIGS. 14 through 22 is provided to show various stages of wafer placement and centering that may be provided using a rotational indexer with an example lateral movement mechanism. The chamber, lift pins, central hub, second hub, tie rods, etc., are omitted from these Figures, and indexer arms 1428 and wafer supports 1432 are represented simply by thick solid lines. The wafer supports 1432 in these Figures are each in the form of a triad of fingers that radiate outward from a common center point at the distal end of one of the indexer arms 1428.

It will be appreciated that while this example features a rotational indexer with 4 indexer arms, other implementations may use a larger or smaller plurality of indexer arms, e.g., 3 indexer arms, 5 indexer arms, 6 indexer arms, etc.

The indexer arms 1428 may have proximal ends that are fixedly connected with a central hub (not shown, but see FIGS. 1 through 2 discussed above) that is rotatable about the center of the array of indexer arms 1428, i.e., about a first axis (not explicitly depicted, but located at the center of the indexer arms 1428). There are various elements in FIGS. 14 through 13 that appear multiple, i.e., four, times within each Figure. To assist with differentiating between different, but identical-looking, instances of such elements, the callouts for these elements may have an A, B, C, or D appended thereto, although it will be understood that reference to the root callout for such elements absent such an appended A, B, C, or D is intended to refer to all of such elements that are depicted.

As can be seen in FIG. 14, there are four pedestals 1408 that are shown, each being positioned in a different quadrant A, B, C. or D. The quadrants are simply provided to facilitate interpretation of the Figures and does not represent structures that would actually be present. The quadrants are based on a rectangular coordinate system that is centered on the first axis.

The pedestals 1408 are shown in solid lines, but there are also pedestals 1408′ that are shown in dotted lines that represent theoretically perfectly placed pedestals, e.g., pedestals that are all positioned with their center points lying exactly on the same circle that is, itself, centered on the first axis and being located at positions on that circle that are exactly equally spaced apart along the circle (these pedestals 1408′ are, in fact, identically placed to their counterpart pedestals 408′ from FIG. 4). As can be seen, the pedestal 1408A is actually perfectly placed, and the solid line circle representing the pedestal 1408A thus masks the dotted line circle representing the “perfect” pedestal position 1408A′. In contrast, each of the pedestals 1408B, 1408C, and 1408D is positioned somewhat off-center from the respective “perfect” pedestal positions 1408B′, 1408C′, and 1408D′. It will be understood that the magnitude of such misalignments in FIGS. 14 through 13 is deliberately exaggerated so as to more clearly convey the concepts discussed herein. In actual practice, the amount of such misalignment is more likely on the order of less than a millimeter or two, e.g., on the order of tens or hundreds of microns, for a system that processes 300 mm diameter wafers (similar displacements may also be observed in systems that process 200 mm or 450 mm wafers). Similarly, the rotational and translational movements discussed below will also be recognized to likely be quite exaggerated, while in actual practice such movements may actually be quite small in nature, e.g., the wafers may typically only be off-center relative to the destination pedestals by distances on the order of tens or hundreds of microns, and the displacements necessary to correct for such small misalignments may be a similar order of magnitude.

Also shown in FIG. 14 are target locations 1442, which coincide with the center points of the pedestals 1408. Target locations 1442′ similarly coincide with the center points of the “perfect” pedestal positions 1408B′, 1408C′, and 1408D′; as can be seen, the pedestals 1408B, 1408C, and 1408D are each offset from the “perfect” pedestal positions 1408B′, 1408C′, and 1408D′ in different directions and to different degrees.

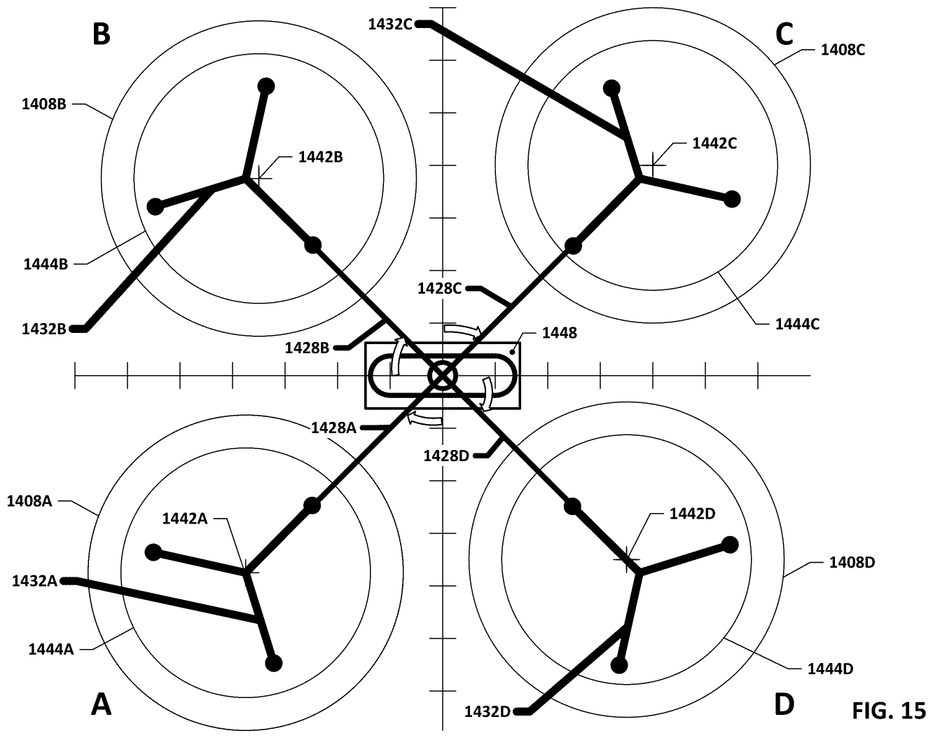

For clarity, FIGS. 15 through 22 omit the “perfect” pedestal locations 1408′ and target locations 1442′, although the pedestals 1408 and target locations 1442 shown in FIG. 14 are retained in each of FIGS. 15 through 22.

In FIG. 14, the rotational indexer is “parked” in a position in which each indexer arm 1428 is located midway between two adjacent wafer processing stations, e.g., between A and B, B and C, C and D, or D and A. Such a configuration may be used when processing operations are being performed on wafers 1444, which are each shown as being centered on the respective pedestals 1408 that support them. The wafers 1444 are shown in heavy weight solid lines in FIGS. 15 through 22 when not being supported by the indexer and lighter weight solid lines when being supported thereby. The indexer arms 1428 are, in this configuration, positioned so as to be as far as possible from each pedestal 1408 so as to minimize the potential effects that the indexer arms 1428 may have on the processing operations that are being performed at each wafer processing station. When such wafer processing operations are complete, the wafers 1444 may be lifted clear of the pedestals 1408 by, for example, lift pins (see earlier discussion and Figures).

In FIG. 15, the rotational indexer has been rotated so as to place each of the wafer supports 1432 underneath one of the wafers 1444, which have all been lifted clear of their respective pedestals 1408 by, for example, lift pins (see earlier discussion and Figures) in order to allow the wafer supports 1432 and the indexer arms 1428 to pass underneath. The wafers 1444 may then be lowered onto the wafer supports 1432 by retracting the lift pins into the pedestals 1408 such that the wafers 1444 are supported by the wafer supports 1432 and the rotational indexer.

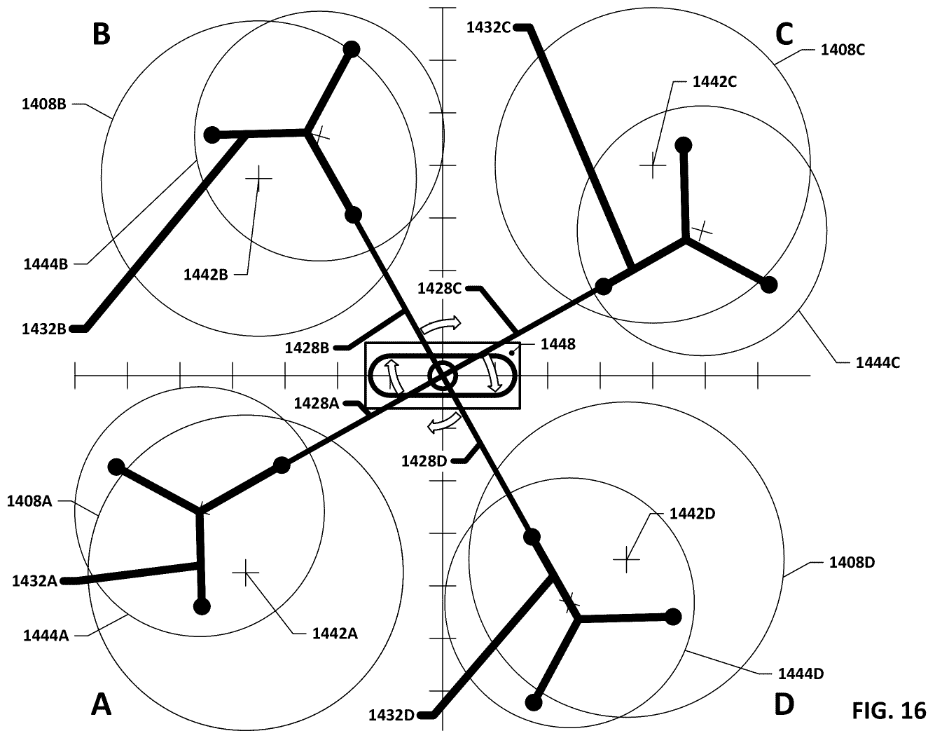

In FIG. 16, the rotational indexer has rotated about the first axis by a small amount, initiating the transfer of the wafers 1444 from the wafer processing stations that they started at to the next wafer processing stations in a clockwise direction (obviously, the wafers 1444 could also be transferred in a counter-clockwise direction depending on the configuration of a particular semiconductor processing tool).

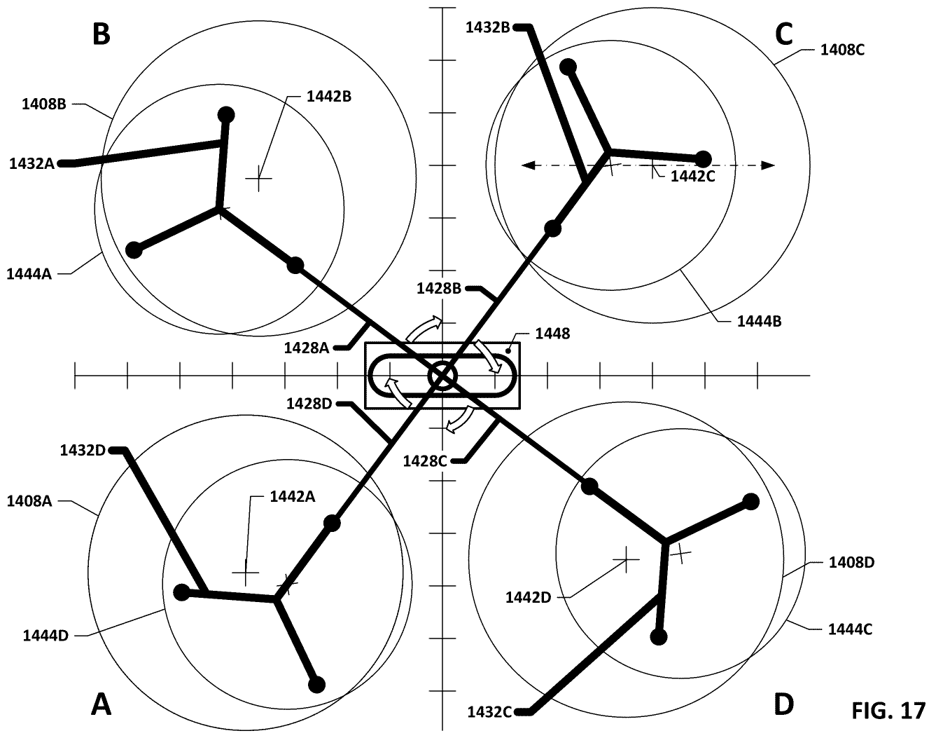

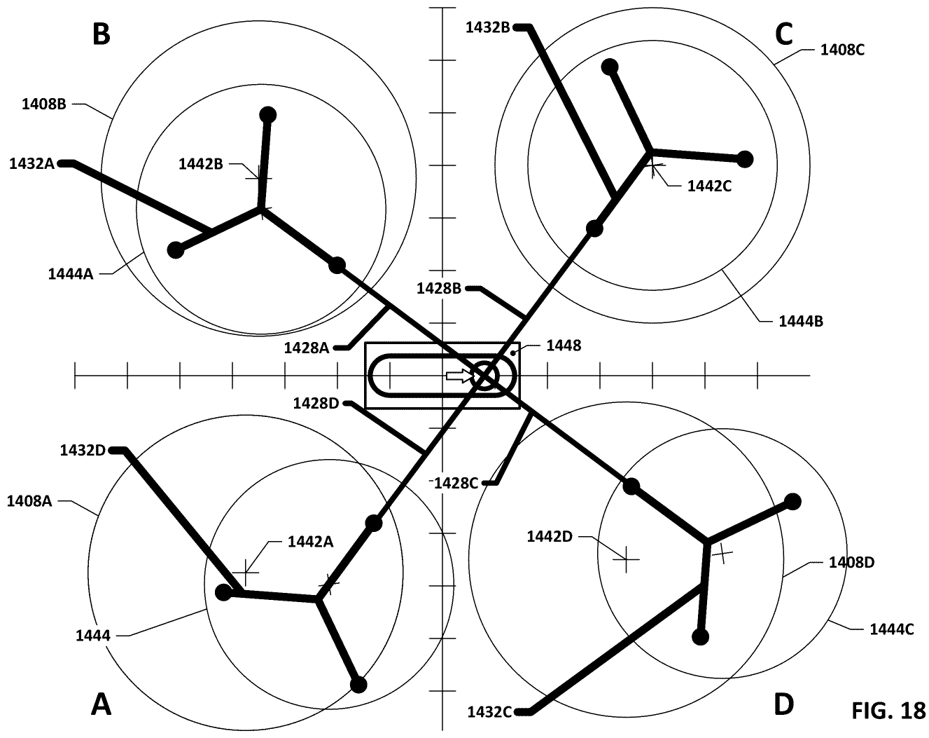

In FIG. 17, the rotational indexer has rotated about the first axis by an amount sufficient to cause the center of the wafer 1444B to be positioned along an axis (represented by the dash-dot-dash double-arrow line in FIG. 17) that a) passes through the target location 1442C and b) is parallel to the translation direction/axis that the lateral movement mechanism 1448 is configured to be able to move the first axis along (in this case, along a left/right direction with respect to the orientation of the Figure). This allows the rotational indexer to be moved, as shown in FIG. 18, using the lateral movement mechanism such that the center of the wafer 1448B is centered on the target location 1442C.

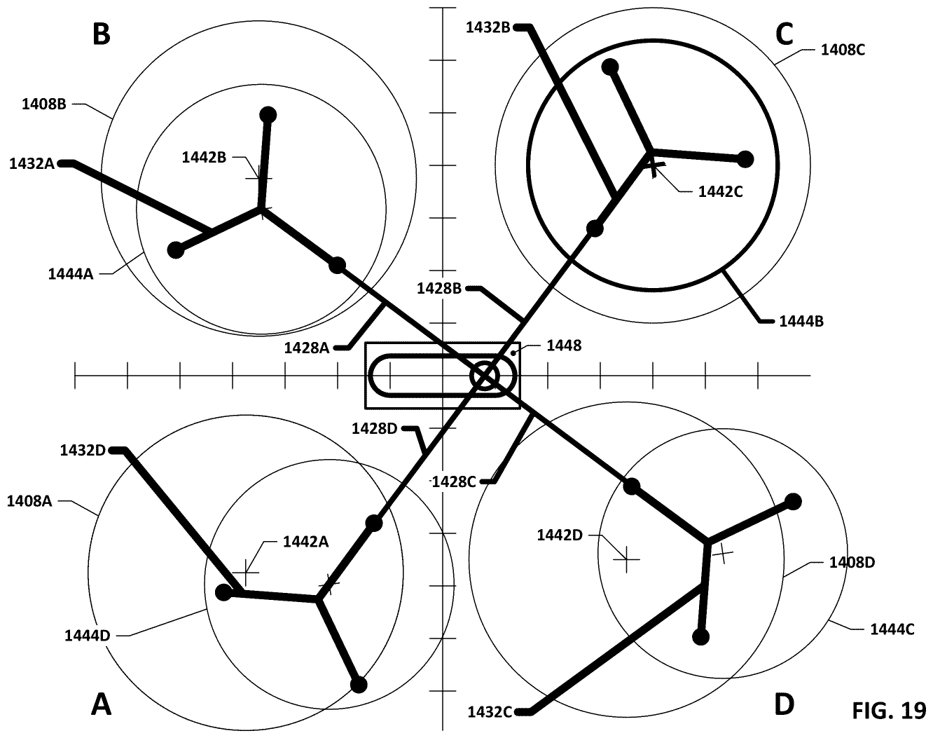

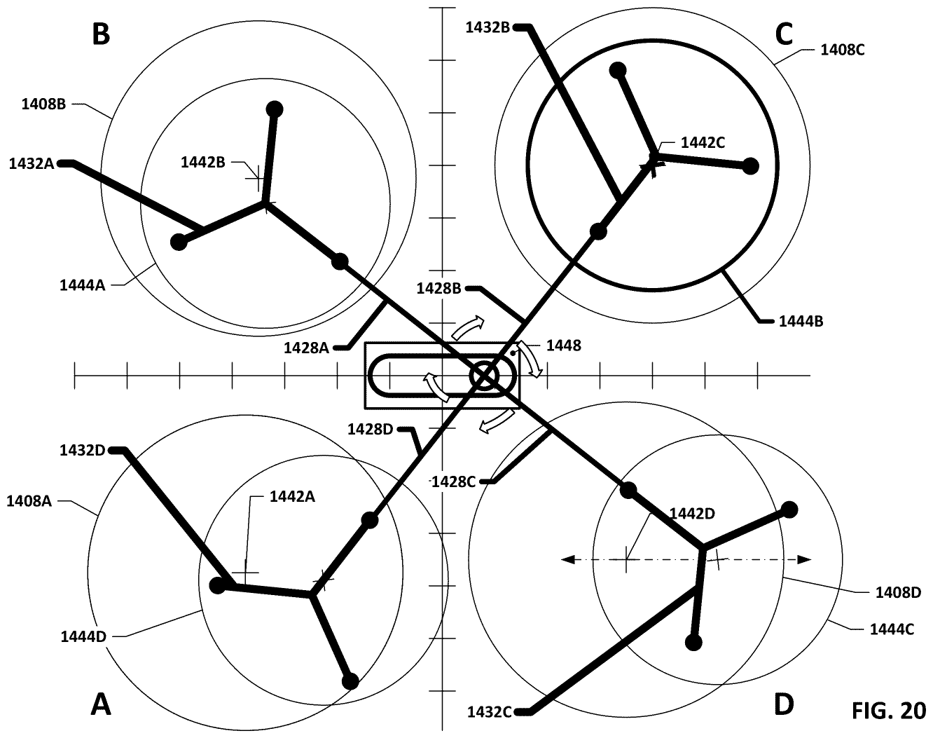

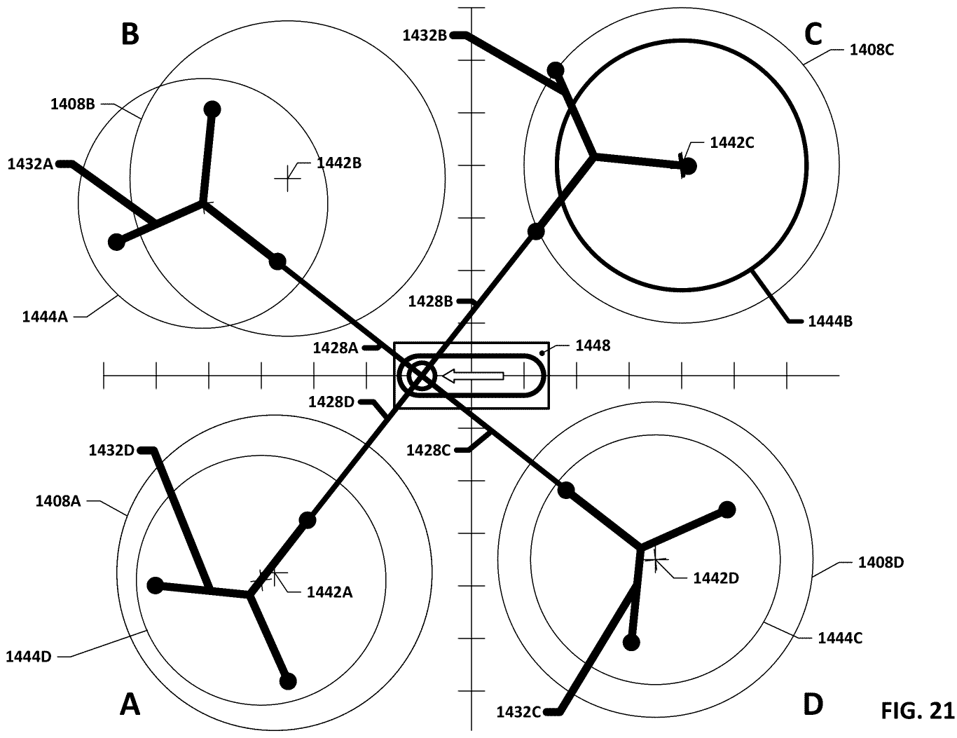

In FIG. 19, the wafer 1444B has been lifted clear of the wafer support 1432B by lift pins, thereby decoupling it from the rotational indexer. The wafer 1444B will thus stay stationary during subsequent movements of the rotational indexer during the wafer transfer operation, e.g., such as when the rotational indexer is rotated, as shown in FIG. 20, so as to bring the center of the wafer 1444C into a location that lies along another axis (represented by the dash-dot-dash double-arrow line in FIG. 20) that a) passes through the target location 1442D and b) is parallel to the translation direction/axis that the lateral movement mechanism 1448 is configured to be able to move the first axis along. This allows the rotational indexer to be moved, as shown in FIG. 21, using the lateral movement mechanism 1448 such that the center of the wafer 1444C is centered on the target location 1442D, as shown in FIG. 20.

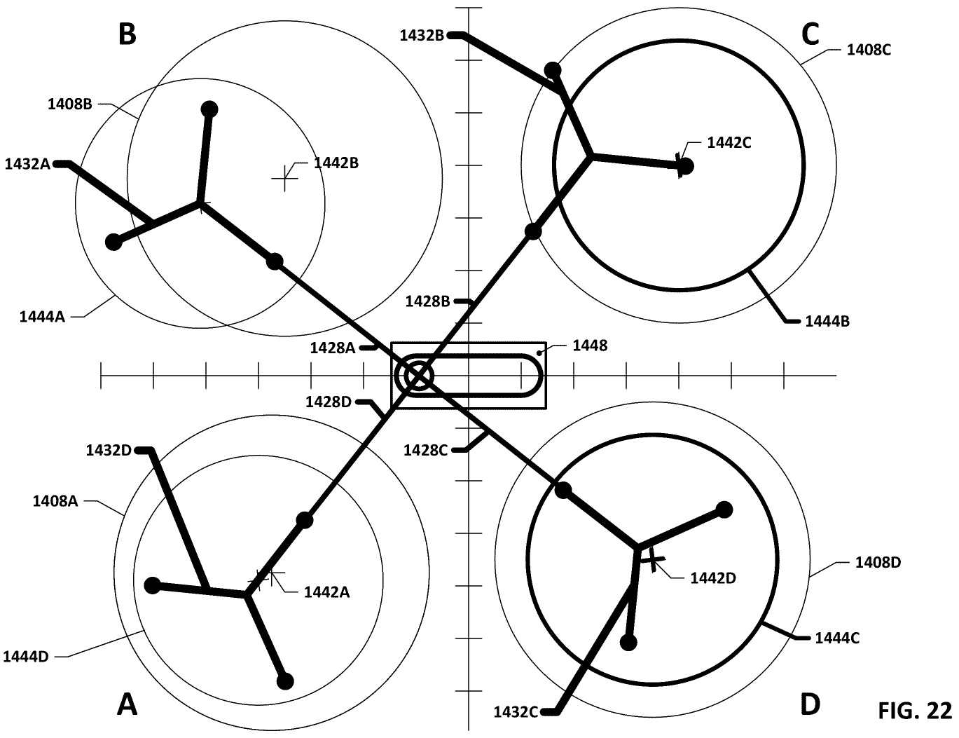

Once the wafer 1444C is centered on the target location 1442D, lift pins may be used to lift the wafer 1444C, e.g., as shown in FIG. 22, so that the wafer 1444C is decoupled from the rotational indexer. It will be understood that the placement and centering of the wafers 1444D and 1444A may be accomplished in a similar manner.

The above example provides an overview of one example technique for using a rotational indexer that is configured to allow the first axis about which the rotational indexer rotates to be moved in a lateral direction. It will be understood that such rotational indexers may be configured in a variety of ways, and that there may be variations on the above-discussed technique. For example, in the above-discussed example, the adjustment/centering of wafers relative to the destination target locations 1442 occurs after the wafers have already been placed on the wafer supports 1432 but prior to, for each transferred wafer, removal of that wafer 1444 from the wafer support 1432 that supports it. Thus, the loading of the wafers 1444 onto the rotational indexer occurs in parallel, e.g., simultaneously, for all of the wafers 1444 but the placement of wafers at their respective destination wafer processing stations occurs in a sequential fashion (although if, by chance, two or more wafers 1444 are actually able to be placed at their respective destination wafer processing stations without requiring intervening rotation of the rotational indexer, then such placement may be performed simultaneously, e.g., in parallel).

However, other implementations may, instead, reverse this process, e.g., placing each of the wafers on to the rotational indexer sequentially and adjusting the lateral position of the rotational indexer and/or the rotation of the rotational indexer in between each such placement operation such that the wafers 1444, when placed, are all positioned at locations that will simultaneously align with the respective destination target locations 1442 at their respective destination wafer processing stations when the rotational indexer is caused to rotate so as to transfer the wafers to the next wafer processing stations. In such an implementation, all of the wafers 1444 may then be lifted off of the rotational indexer simultaneously when the rotational indexer has been rotated so as to align all of the centers of the wafers 1444 with the respective destination target locations 1442 for those wafers 1444.

It will also be recognized that sequential wafer placement may also, in some implementations, be performed both during the loading of the wafers 1444 onto the rotational indexer and during subsequent placement of the wafers 1444 at the destination wafer processing stations, although this may unnecessarily increase the amount of time needed to complete a given wafer transfer operation.

It will also be understood that in systems with other types of lateral movement mechanisms, there may be modification of the above-discussed technique. For example, in a system with a biaxial lateral movement mechanism, e.g., an XY stage that can be translated independently along two orthogonal axes, the rotational adjustment of the rotational indexer in between wafer placement operations discussed above with respect to FIGS. 14 through 22 may be avoided, e.g., bidirectional lateral movement of the first axis may instead be used to bring the center of a given wafer 1444 into alignment with the destination target location 1442. In another example, the first axis may be movable along a non-linear path, in which case the linear dash-dot-dash axes in FIGS. 17 and 20 may instead be non-linear. Such a non-linear path may, for example, represent the path along which the center of a wafer to be placed may travel when the lateral movement mechanism is actuated so as to move the first axis laterally.

It will be further understood that while FIGS. 14 through 22 depict the various movements discussed above as occurring in a discrete, disconnected fashion, some of the movements depicted in FIGS. 14 through 22 may be performed simultaneously. For example, rotation of the rotational indexer, e.g., by actuation of the indexer drive assembly, and translation of the rotational indexer, e.g., by the lateral movement mechanism, may be caused to occur at least simultaneously.

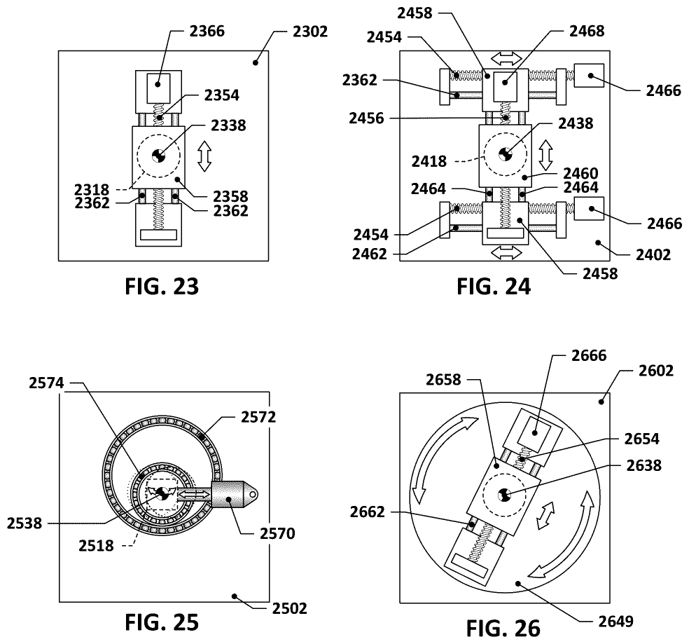

As noted above, the lateral movement mechanisms that may be used to move the rotational indexer, and thus the first axis of the rotational indexer, may take a variety of forms. FIGS. 23 through 26 provide various examples of some such lateral movement mechanisms, although other such mechanisms will be apparent to those of ordinary skill in the art, and this disclosure is to be understood to encompass such alternative such lateral movement mechanisms as well.

In FIG. 23, a single-axis lateral movement mechanism 2348 is shown that features guides 2362 that are fixedly mounted with respect to a chamber 2302. A stage 2358 is slidably mounted to the guides 2362 such that it can translate along the guides 2362 along a single axis. The guides 2362 may be any suitable bearing surface that may guide the motion of the stage 2358, e.g., round steel bars. The perspective of FIG. 23 is from below, looking up at the underside of the chamber 2302; indexer drive assembly 2318 may be mounted on top of the stage 2358. The lateral movement mechanism 2348 may also include a motor 2366 that, responsive to inputs received from a controller, may rotate a linear screw 2354 that may, in passing through a threaded nut that is fixed with respect to the stage, drive motion of the stage 2358 along the guides 2362, as indicated by the double-ended arrow shown in FIG. 23. In such a lateral movement mechanism 2348, the indexer drive assembly 2318 may be supported by and fixed with respect to (at least in the lateral directions) the stage 2358. Thus, the first axis 2338 may be translatable in a direction parallel to the guides 2362. Such a mechanism may, for example, be used in the example semiconductor processing tool of FIGS. 14 through 22.

In FIG. 24, a bi-axial lateral movement mechanism 2448 is depicted that features first guides 2462 that are fixedly mounted with respect to a chamber 2402. A first stage or stages 2458 may be slidably mounted to the first guides 2462 and may be actuated using first motor or motors 2466 that may drive first linear screw or screws 2454, thereby causing the first stage or stages 2458 to translate linearly in the left-right direction with respect to FIG. 24. The first stage or stages 2458 may similarly support a second guide or guides 2464 that may slidably support a second stage 2460. The second stage 2460 may be caused to translate linearly along the second guides 2464 through actuation of second motor 2468, which may drive a second linear screw 2456 that causes the second stage 2460 to travel along the second guides 2464. An indexer drive assembly 2418 may be supported by the second stage 2460, thus allowing the first axis 2438 of the indexer drive assembly 2418 to be translated along both the left/right and up/down directions (relative to FIG. 24). As with FIG. 23, FIG. 24 depicts a view from underneath the chamber 2402 looking up. By driving both the first motor(s) 2466 and the second motor(s) 2468 at different speeds and/or amounts, e.g., responsive to signals received from a controller, the first axis 2438 may be caused to follow virtually any desired path within the region permitted by the movement constraints of the first and second guides 2462 and 2464.

In FIG. 25, a lateral movement mechanism 2548 is depicted that features a linear actuator 2570 with an extensible piston that is fixedly coupled to an indexer drive assembly 2518. The indexer drive assembly 2518 may be rotatably supported relative to the chamber 2502 by a first bearing 2572 that supports a second bearing 2574 that supports the indexer drive assembly 2518. The first bearing 2572 and the second bearing 2574 may be mounted such that their rotational centers are offset from one another, forming an eccentric. The piston is able to be controllably extended or retracted from a body of the linear actuator that is pinned in place relative to chamber 2502 such that the body of the linear actuator 2570 is able to rotate relative to the chamber 2502. Thus, when the linear actuator 2570 is actuated so as to retract or extend the piston, the indexer drive assembly 2518 will be caused to swing along an arcuate path as the second bearing 2574 rotates about the center of the first bearing 2572. The orientation of the indexer driver assembly 2518 in such an implementation may also rotate in tandem with the rotation of the linear actuator 2570, although such rotation may be slight for small movements of the linear actuator.

In FIG. 26, a single-axis lateral movement mechanism 2648 is shown that features guides 2662 that are fixedly mounted with respect to a first portion of a turntable 2649. The turntable 2649 may have a second portion that is fixed in space relative to a chamber 2602, and may be controllable, e.g., via an electric motor, such that the first portion of the turntable (and thus the guides 2662 and other equipment that may be supported thereby) may be caused to rotate relative to the second portion of the turntable and, thus, the chamber 2602. A stage 2658 is slidably mounted to the guides 2662 such that it can translate along the guides 2662 along a single axis. The guides 2662 may be any suitable bearing surface that may guide the motion of the stage 2658, e.g., round steel bars. An indexer drive assembly 2618 may be mounted on top of the stage 2658. The lateral movement mechanism 2648 may also include a motor 2666 that, responsive to inputs received from a controller, may rotate a linear screw 2654 that may, in passing through a threaded nut that is fixed with respect to the stage, drive motion of the stage 2658 along the guides 2662, as indicated by the double-ended arrow shown in FIG. 26. In such a lateral movement mechanism 2648, the indexer drive assembly 2618 may be supported by and fixed with respect to (at least in the lateral directions) the stage 2658. Thus, the first axis 2638 may be translatable in a direction parallel to the guides 2662. By rotating the first portion of the turntable 2649 and translating the stage 2658, the first axis 2638 may be caused to be moved to any location within a circle centered on the center of rotation of the first portion of the turntable 2649 and having a radius equal to the furthest distance that the first axis 2638 can be moved to away from the center of rotation of the first portion of the turntable 2649 by the stage 2658. If desired, the indexer arm assembly may be counter-rotated by the indexer drive assembly 2618 at the same rate (but in the opposite direction) as the first portion of the turntable 2649 is rotated such that when the first portion of the turntable 2649 is rotated, the indexer arm assembly does not change its orientation (although it may move laterally). Such a mechanism may, for example, be used in the example semiconductor processing tool of FIGS. 14 through 22.

It will be appreciated that the range of lateral displacement provided by such lateral movement mechanisms does not need to be that large, especially in comparison with typical movement mechanisms found in wafer transport equipment. For example, lateral movement mechanisms that are suitable for use in some of the implementations discussed herein may have a maximum lateral displacement capability of 200 mm or less, 20 mm or less, or even as low as 2 mm or less.

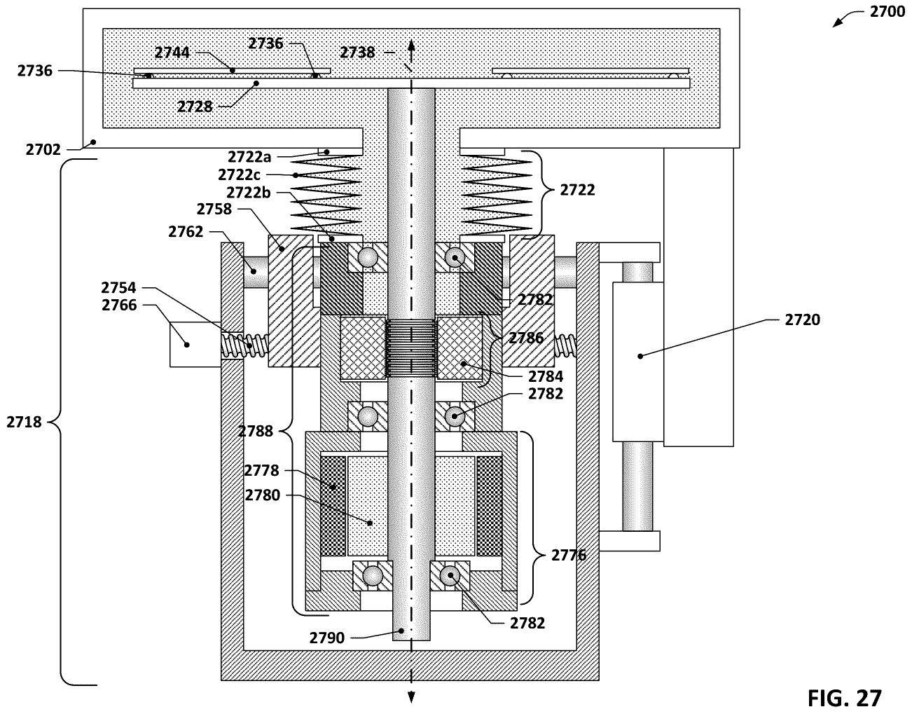

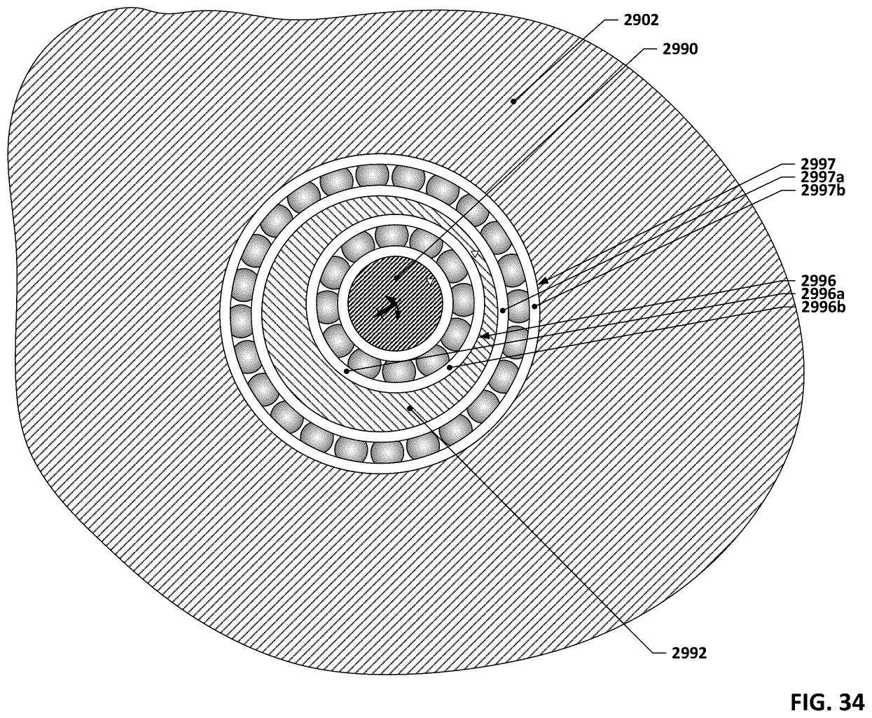

As discussed, indexers that are equipped with some form of lateral displacement mechanism to facilitate lateral translation or movement of the first axis may require unconventional sealing strategies to accommodate both rotational and translational movement while still maintaining a seal that is able to support a vacuum environment within the semiconductor manufacturing tool's processing chamber and ambient atmosphere exterior to the chamber. Examples of two such sealing mechanisms are discussed below with respect to FIGS. 27 through 37.

In FIG. 27, a semiconductor processing tool 2700 is shown that includes a chamber 2702 and an indexer driven by an indexer drive assembly 2718. The indexer has a plurality of indexer arms 2728 that each have wafer supports at their distal ends that are configured to support wafers 2744 using contact pads 2736. The indexer arms 2728 are fixedly connected with a shaft 2790 via a central hub (not shown, but see FIG. 1, for example) that is configured to rotate about a first axis 2738 when actuated by a motor 2776. The motor 2776 may, for example, include a stator 2778 that is fixed in place with respect to a motor housing 2788 and a rotor that is fixed in place with respect to the shaft 2790. The shaft 2790 may be rotatably supported relative to the motor housing 2788 by rotational bearings 2782.

The motor housing 2788 may also include a rotational seal that allows for the shaft 2790 to pass therethrough and rotate while allowing a vacuum environment to be maintained on one side of the seal and an atmospheric pressure environment to be maintained on the other side of the seal. While it will be understood that different types of such seals may be used, the depicted example features a ferrofluidic seal 2786 which features magnets 2784 that generate a magnetic field across the circumferential gap between the shaft 2790 and the magnets 2784. The shaft 2790 may, as shown, have a zone of larger- and smaller-diameter segments arranged in a linear fashion along the first axis 2738 in the region of the magnets 2784. A ferrofluid (the dark material occupying the gap between the magnets 2784 and the shaft 2790) may, due to the magnetic field that is generated, form a series of ferrofluidic O-rings that span between the larger-diameter portions of the shaft 2790 and the magnets 2784, with one of the smaller-diameter portions of the shaft 2790 located in between each ferrofluidic O-ring.

In this example, the motor housing is able to be translated laterally by a lateral movement mechanism that includes a motor 2766 that drives a linear screw 2754 that causes a stage 2758 to translate left or right (with respect to the orientation of FIG. 27) responsive to rotation of the linear screw 2754. The translation of the stage 2758 may, for example, be constrained by guides 2762, which may act as rails that limit the motion of the stage 2758 to unidirectional motion, similar to the mechanism shown in FIG. 23. Of course, other implementations may use other lateral movement mechanisms, e.g., such as are shown in FIG. 24 or 25, or otherwise known in the art.

The above-described semiconductor processing tool 2700 thus has the capability of rotating the shaft 2790 about the first axis 2738 and also moving the first axis 2738 (and thus the shaft 2790 and the indexer) laterally relative to the chamber. The rotational seal that is provided by the ferrofluidic seal 2786 may provide the seal across the rotational interface for the shaft 2790. However, in order to provide a seal that can be maintained during the lateral movement of the shaft 2790 relative to the chamber 2702, an additional sealing mechanism must be provided. This additional sealing mechanism takes the form of a bellows seal 2722 in FIG. 27. The bellows seal 2722 may have a first end 2722a, a second end 2722b, and a flexible bellows portion 2722c that spans between the first end 2722a and the second end 2722b. The first end 2722a may be fixed in space with respect to (and clamped against so as to form a seal) the chamber 2702, and the second end 2722b may be fixed in space with respect to (and clamped against so as to form a seal) the motor housing 2788, thereby sealing off the interior volume of the chamber 2702 and allowing a vacuum to be maintained therein (as represented by the light grey shading that fills the interior of the chamber 2702).

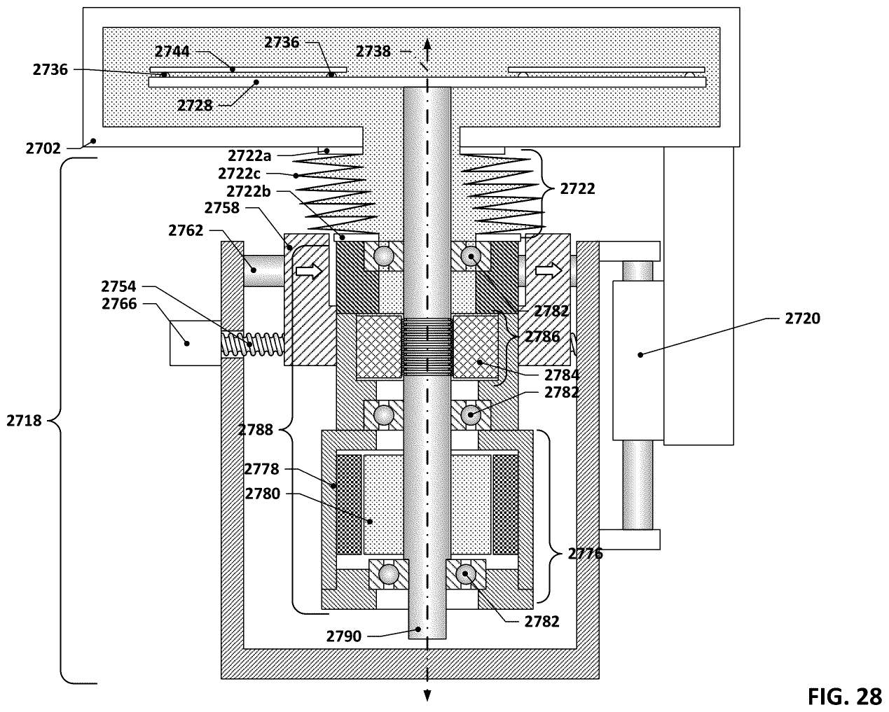

In some implementations, such as that depicted in FIG. 27, the indexer drive assembly 2718 may also include, or be attached to, a lift actuator 2720 that may be actuated to cause the motor housing 2788 (or at least the shaft 2790) to move up and down relative to the chamber 2702. This may allow the indexer arms 2728 to change elevation, e.g., to allow the indexer arms 2728 to be moved into recesses within the chamber 2702 when not in use so as to have less potential impact on processing conditions within the chamber 2702. The bellows seal 2722 may permit such movement of the motor housing 2788 relative to the chamber 2702, but may also, as shown in FIG. 28, allow for some small amount of lateral displacement between the shaft 2790 and the chamber 2702. While bellows seals such as bellows seal 2722 are typically not designed to accommodate large amounts of such displacement, they are capable of accommodating the small amounts of displacement that would typically be seen in a rotational indexer having a wafer placement adjustment capability as discussed earlier herein.

The bellows seal 2722 and the rotational seal, e.g., provided by the ferrofluidic seal 2786, as well as the structure that spans between them, may be thought of as a rotational and translational seal mechanism, i.e., an assembly that allows for both rotational and translational movement of the shaft 2790 (about the first axis 2738 and at least in one or more directions perpendicular to the first axis 2738—in some instances, the rotational and translational seal mechanism may also allow for some translational movement along the first axis 2738 as well) relative to the chamber 2702 while still allowing a vacuum environment to be maintained within the chamber 2702 and atmospheric conditions to be maintained where the motor 2776 is located. Generally speaking, the rotational and translational seal mechanism may have a first portion that is fixed in space relative to, and sealed against, the shaft (and which may actually be the shaft in some cases) of the rotational indexer and a second portion that is fixed in space relative to, and sealed against, the housing or other structure that is fixedly mounted thereto. The rotational and translational seal mechanism may also have one or more third portions that are arranged to provide a seal interface during rotational and/or translational movement of the shaft relative to the chamber. For example, in the implementation of FIG. 27, the first portion of the rotational and translational seal mechanism may be understood to be provided by the shaft 2790, the second portion of the rotational and translational seal mechanism may be understood to be provided by the first end 2722a of the bellows seal, and the one or more third portions of the rotational and translational seal mechanism may be understood to be provided by the flexible bellows portion 2722c, the second end 2722b of the bellows seal 2722, the portions of the motor housing 2788 in between the second end 2722b of the bellows seal 2722, the magnets 2784, and the ferrofluid that is magnetically retained in the gap between the shaft 2790 and the magnets 2784.

It will be recognized, of course, that a rotational and translational seal mechanism as provided in FIGS. 27 and 28 may also be used in systems that do not have a lift actuator, i.e., where the positioning of the indexer arms 2728 along the first axis 2738 within the chamber 2702 is not able to be adjusted. The use of the bellows seal 2722 in semiconductor processing tools to seal a translational interface in which the translation axis is orthogonal to the center axis of the bellows seal is thought to be a new configuration of use for a bellows seal.

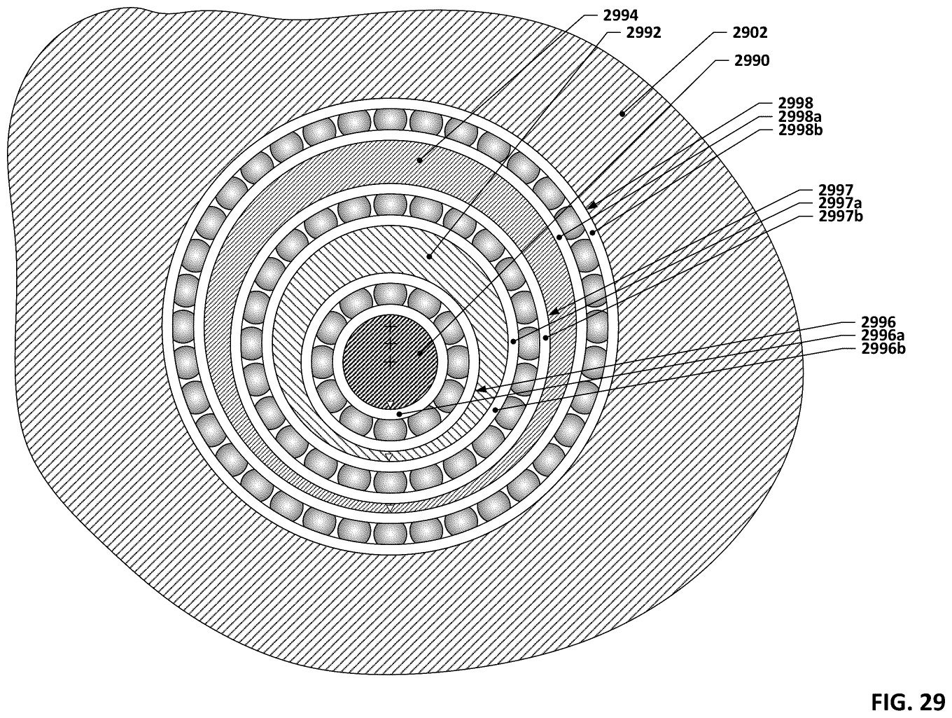

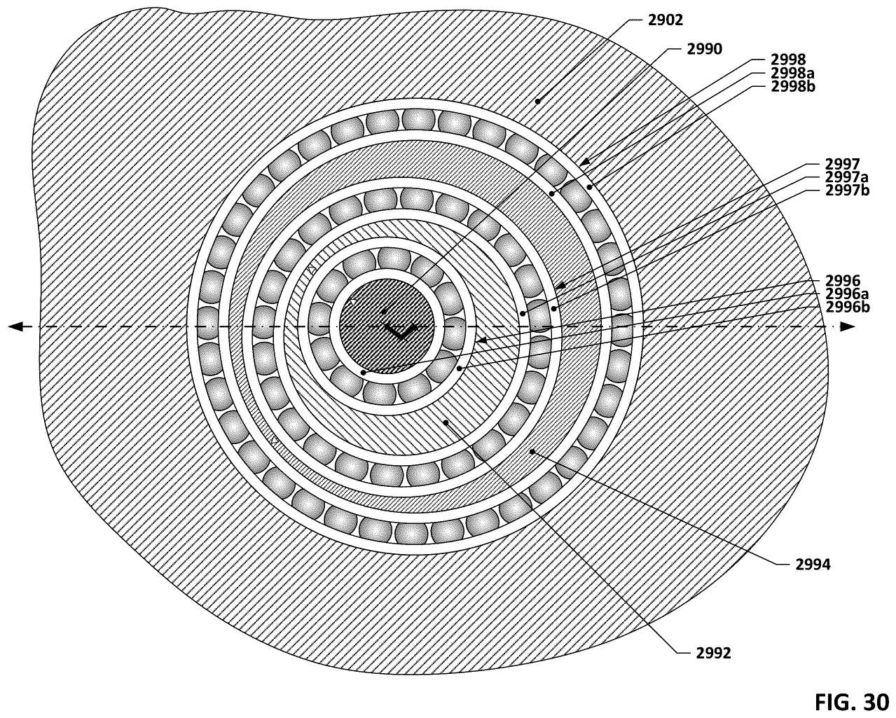

FIGS. 29 through 37 depict various implementations of another rotational and translational seal mechanism or semiconductor processing tools using such a rotational and translational seal mechanism.

FIG. 29 depicts an example arrangement of rotational interfaces for providing a rotational and translational seal mechanism. In FIG. 29, a first rotational interface 2996, a second rotational interface 2997, and a third rotational interface 2998 are shown, as are a first eccentric mount portion 2992 and a second eccentric mount portion 2994. The rotational interfaces of FIG. 29 are shown as being located in a portion of a chamber 2902, although they may also be located in other locations and assembled with other components depending on the particular configuration adopted.

The first rotational interface 2996 may have a corresponding first portion 2996a and a corresponding second portion 2996b; similarly, the second rotational interface 2997 may have a corresponding first portion 2997a and a corresponding second portion 2997b and the third rotational interface 2998 may have a corresponding first portion 2998a and a corresponding second portion 2998b.

For example, the first portion 2996a of the first rotational interface 2996 may include an inner bearing race that is pressed onto the shaft 2990, as well as part of the shaft 2990 itself, thereby causing the first portion 2996a of the first rotational interface to be fixed in space with respect to the central hub of the indexer, which may be mounted to the end of the shaft 2990. Similarly, the second portion 2996b of the first rotational interface 2996 may include an outer bearing race that is pressed into the first eccentric mount portion 2992 as well as portions of the first eccentric mount portion 2992.

It will be understood that the rotational interfaces shown in FIG. 29 may also each include a corresponding rotational seal that is not shown in FIG. 29 but which is able to provide a seal between adjacent components that are able to rotate relative to one another; later Figures may be referenced for examples thereof.

The rotational interfaces shown in FIG. 29 form a double-eccentric configuration. In such a configuration, the center or axis of rotation of the first rotational interface 2996, which may be referred to as the first axis, is offset from the center or axis of rotation of the second rotational interface 2997, which may be referred to as the second axis, by some non-zero distance in a direction perpendicular to the first axis. Similarly, the center or axis of rotation of the third rotational interface 2998, which may be referred to as the third axis, is offset from the second axis by some non-zero distance in a direction perpendicular to the second axis. The first, second, and third axes may all be parallel to one another.

The configuration of rotational interfaces shown in FIG. 29 permit the shaft 2990 to translate bidirectionally relative to the chamber 2902 for small distances, e.g., by distances limited by the total amount of eccentricity present in the double-eccentric configuration. When the shaft 2990 is caused to move laterally, i.e., in a direction parallel to the plane of the paper for FIG. 29, by an actuation mechanism of some sort, e.g., such as the lateral movement mechanisms discussed with respect to FIGS. 23 through 24, the rotational interfaces and the eccentric mount portions of FIG. 29 will automatically rotate to accommodate such movement due to the forces that are transmitted through each rotational interface.

FIGS. 30 through 33 show examples of such movement. In FIG. 30, the shaft 2990 is centered along a left/right axis. Thick heavy line segments link the first axis about which the shaft 2990 rotates to the second axis, about which the first eccentric mount portion 2992 rotates and then from the second axis to the third axis, about which the second eccentric mount portion 2994 rotates.

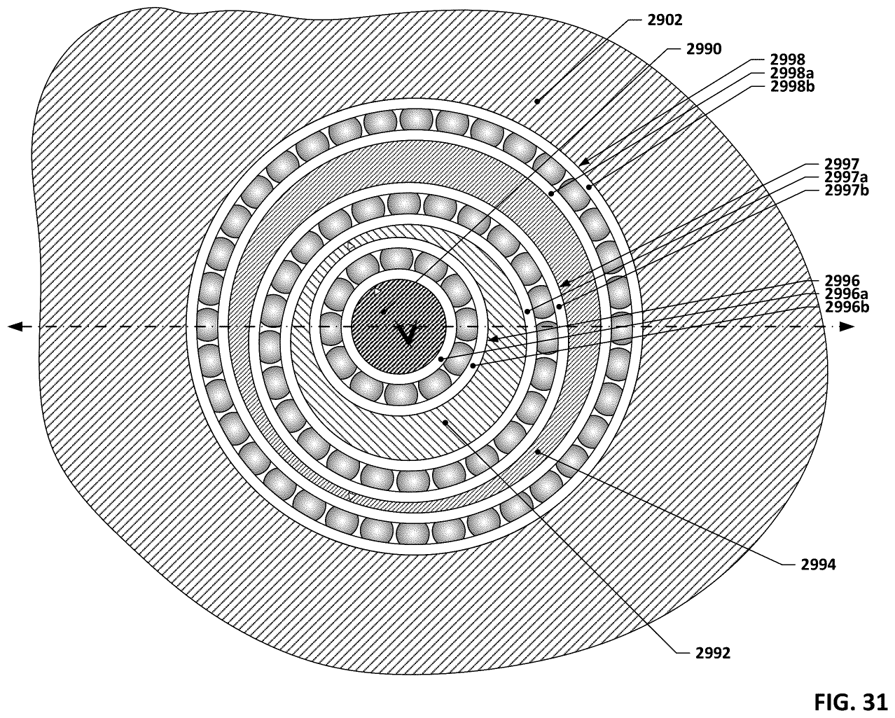

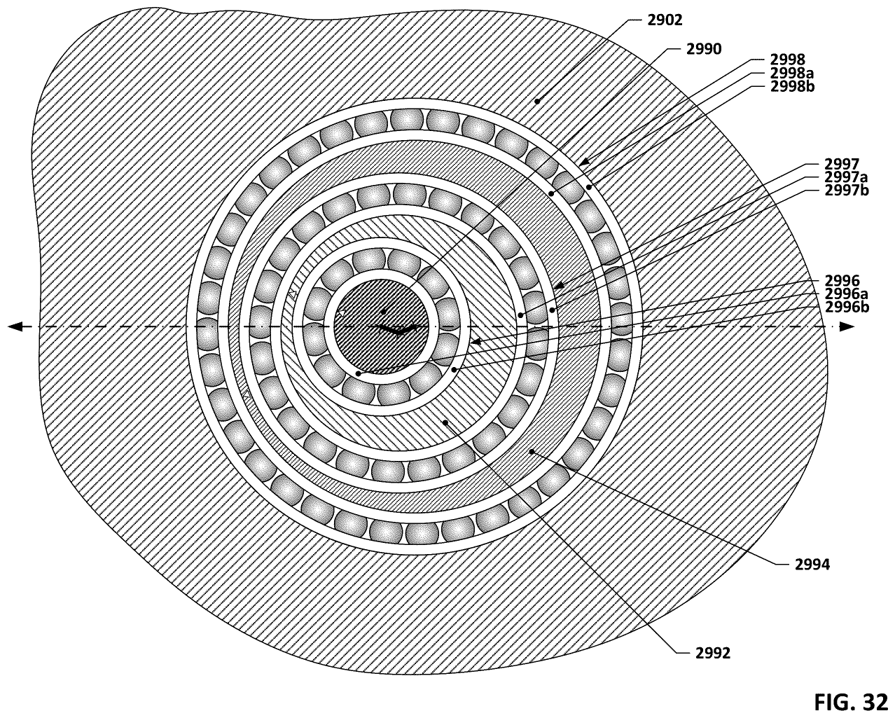

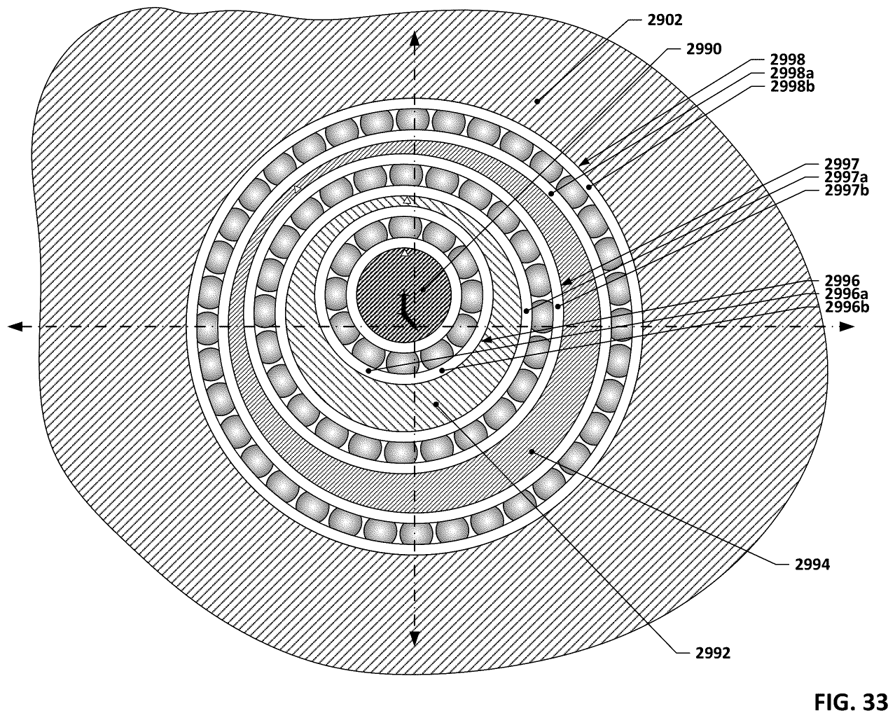

In FIG. 31, the shaft 2990 has been moved to the right along the left/right axis, thereby causing the first axis to come closer to the third axis. In FIG. 32, the shaft 2990 has instead been moved to the left along the left/right axis, thereby causing the first axis to be further from the third axis. As can be seen, the depicted configuration is able to accommodate unidirectional movement of the shaft 2990 relative to the chamber 2902 for at least movement between the depicted locations of FIGS. 31 and 32 (and also some further movement beyond those two locations—although movement of the shaft 2990 that is sufficient to cause the first axis, second axis, and third axis to all line up along the left/right axis may cause binding of the rotational interfaces and it may thus be desirable to limit the amount of left/right movement to avoid such scenarios.

The arrangement shown in FIGS. 29 through 32 is not limited to only accommodating unidirectional motion along the left/right axis, but can also, as mentioned above, accommodate bidirectional movement. In FIG. 33, the shaft 2990, and thus the first axis, has been moved to the left of the third axis and has also been moved above the third axis.

In the case where the motion of the first axis is constrained to follow anon-linear path, e.g., such as may occur when an actuation mechanism such as that of FIG. 25 is used, a simplified arrangement of the rotational interfaces shown in FIGS. 29 through 33 may be used. In this simplified arrangement, there is only one eccentric mount portion and only the first rotational interface and the second rotational interface are provided. The second eccentric mount portion and the third rotational interface are omitted. In such an implementation, the first axis may be constrained to move along an arcuate path that is centered on the second axis—although such motion may still involve translation along multiple axes.

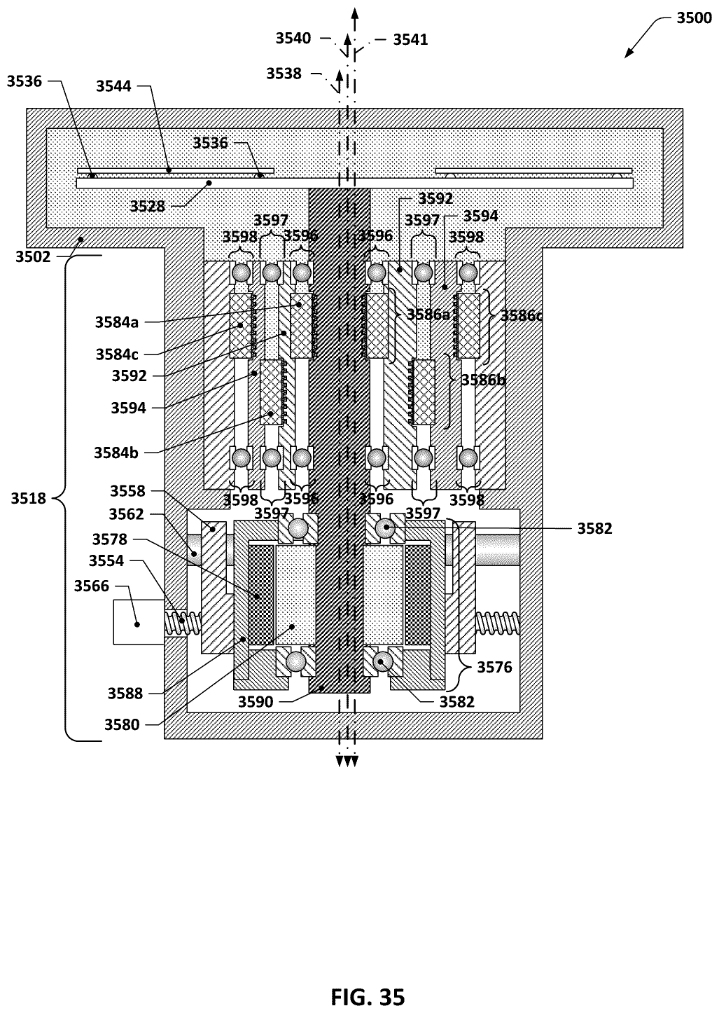

In FIG. 35, a semiconductor processing tool 3500 is shown that includes a chamber 3502 and an indexer driven by an indexer drive assembly 3518. The indexer has a plurality of indexer arms 3528 that each have wafer supports at their distal ends that are configured to support wafers 3544 using contact pads 3536. The indexer arms 3528 are fixedly connected with a shaft 3590 via a central hub (not shown, but see FIG. 1, for example) that is configured to rotate about a first axis 3538 when actuated by a motor 3576. The motor 3576 may, for example, include a stator 3578 that is fixed in place with respect to a motor housing 3588 and a rotor that is fixed in place with respect to the shaft 3590. The shaft 3590 may be rotatably supported relative to the motor housing 3588 by rotational bearings 3582.

The semiconductor processing tool 3500 may also include a rotational and translational seal mechanism that allows for the shaft 3590 to pass therethrough and both rotate and translate relative to the chamber 3502 while allowing a vacuum environment to be maintained on one side of the rotational and translational seal mechanism and an atmospheric pressure environment to be maintained on the other side of the rotational and translational seal mechanism. In this example, the rotational and translational seal mechanism is provided by a double-eccentric arrangement of three rotational interfaces and accompanying rotational seals, similar to the arrangement discussed above with respect to FIGS. 29 through 33.

In this example, the motor housing is able to be translated laterally by a lateral movement mechanism that includes a motor 3566 that drives a linear screw 3554 that causes a stage 3558 to translate left or right (with respect to the orientation of FIG. 35) responsive to rotation of the linear screw 3554. The translation of the stage 3558 may, for example, be constrained by guides 3562, which may act as rails that limit the motion of the stage 3558 to unidirectional motion, similar to the mechanism shown in FIG. 23. Of course, other implementations may use other lateral movement mechanisms, e.g., such as are shown in FIG. 24 or 25, or otherwise known in the art.

The above-described semiconductor processing tool 3500 thus has the capability of rotating the shaft 3590 about the first axis 3538 and also moving the first axis 3538 (and thus the shaft 3590 and the indexer) laterally relative to the chamber 3502.

The rotational and translational seal mechanism of FIG. 35 may accommodate both types of motion, and may include a first eccentric mount portion 3592, a second eccentric mount portion 3594, a first rotational interface 3596, a second rotational interface 3597, and a third rotational interface 3598. The first rotational interface 3596 may include, for example, rotational bearing elements, such as the bearings that are located at the top and bottom of the first eccentric mount portion 3592, as well as a rotational seal, such as ferrofluidic seal 3586a, which may include magnets 3584a that encircle the shaft 3590 and that may generate a magnetic field that causes a ferrofluid (indicated by the dark gray material in between the shaft 3590 and the magnets 3584a) to form multiple, axially spaced-apart ferrofluidic O-rings that seal the circumferential gap between the shaft 3590 and the magnets 3584a.

Similarly, the second rotational interface 3597 and the third rotational interface 3598 may also include corresponding rotational bearing elements as well as corresponding rotational seals having magnets 3584b and 3584c, respectively, that encircle the first eccentric mount portion 3592 and the second eccentric mount portion 3594, respectively. The magnetic fields from the magnets 3584b and 3584c may generate corresponding magnetic fields that cause ferrofluid that is located in the circumferential gaps between the first eccentric mount portion 3592 and the magnets 3584b and between the second eccentric mount portion 3594 and the magnets 3584c to form respective axial arrangements of ferrofluidic O-rings that seal such gaps. Such an arrangement, as can be seen, results in three separate rotational axes that come into play. Such rotational axes include the first axis, about which the shaft 3590 is able to rotate relative to the chamber 3502, as well as a second axis, about which the first eccentric mount portion 3592 can rotate relative to the second eccentric mount portion 3594, and a third axis, about which the second eccentric mount portion 3594 can rotate relative to the chamber 3502.

When the lateral movement mechanism that is provided using the motor 3566, linear screw 3554, the guides 3562, and the stage 3558 is actuated so as to cause the shaft 3590 to translate along the guides 3562, the two eccentric mount portions 3592 and 3594 may passively rotate relative to each other (and the chamber 3502 and the shaft 3590) as necessary in order to maintain the position of the first axis 3538 along an axis that is parallel to the translation axis. This allows the rotational and translational seal mechanism of FIG. 35 to not only accommodate pure rotational movement via the first rotational interface 3596, but also some amount of lateral displacement via the interplay between the first eccentric mount portion 3592, the second eccentric mount portion 3594, the first rotational interface 3596, the second rotational interface 3597, and the third rotational interface 3598. Since each such element only rotates with respect to each adjacent such element, purely rotational seals may be used to seal between the shaft 3590 and the chamber 3502.

Such an arrangement may be used to seal off the interior volume of the chamber 3502 and allow a vacuum to be maintained therein (as represented by the light grey shading that fills the interior of the chamber 3502).

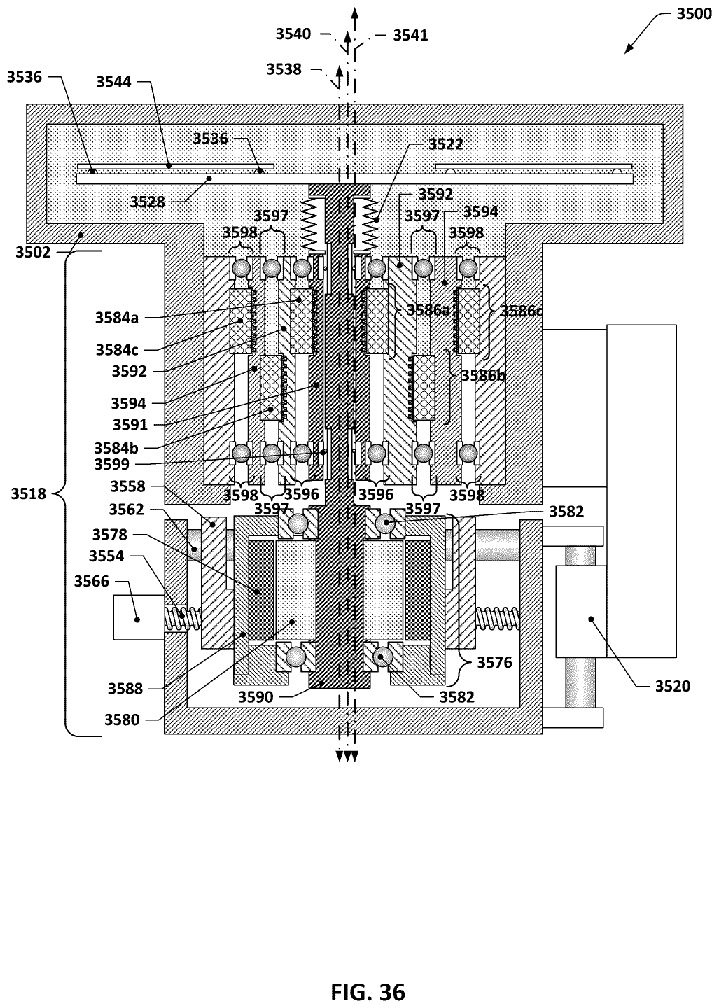

In FIG. 35, the indexer depicted has no translation capability along the indexer rotational axis-since the double-eccentric arrangement of rotational interfaces and seals accommodates both lateral translation and rotation relative to the chamber 1202, there is no need for a bellows seal or similar such device. FIG. 36, however, depicts a version of the semiconductor processing tool 35 in which a lift capability has been added.

In FIG. 36, the motor housing 3588 is not only able to be translated laterally relative to the chamber 3502, but also axially along the first axis by way of a lift actuator 3520. The shaft 3590 also passes through a sleeve 3591 that is rotationally fixed with respect to the shaft 3590, e.g., through the use of a keying feature or similar anti-rotation feature, but allows the shaft 3590 to translate along the first axis relative to the sleeve 3591, e.g., via linear bearings 3599. Thus, when the lift actuator is actuated to cause the motor housing 3588 to move up or down, the shaft 3590 will move up or down relative to the sleeve 3591 and cause the indexer arms to move up or down within the chamber 3502.

Since the shaft 3589 is able to extend out of or retract into the sleeve 3591, a bellows seal 3522 may be used to seal between the two components while still allowing the two components to translate relative to one another along the first axis 3538. In such an arrangement, a first end of the bellows seal 3522 may be fixed in space with respect to a center hub of the indexer (see FIG. 1; not shown in FIG. 36), and a second end of the bellows seal 3522 maybe fixed in space with respect to the sleeve 3591 (which may also be fixed in space with respect to the first portion of the first rotational interface 3596). A flexible bellows portion may span between the first and second ends of the bellows seal 3522.

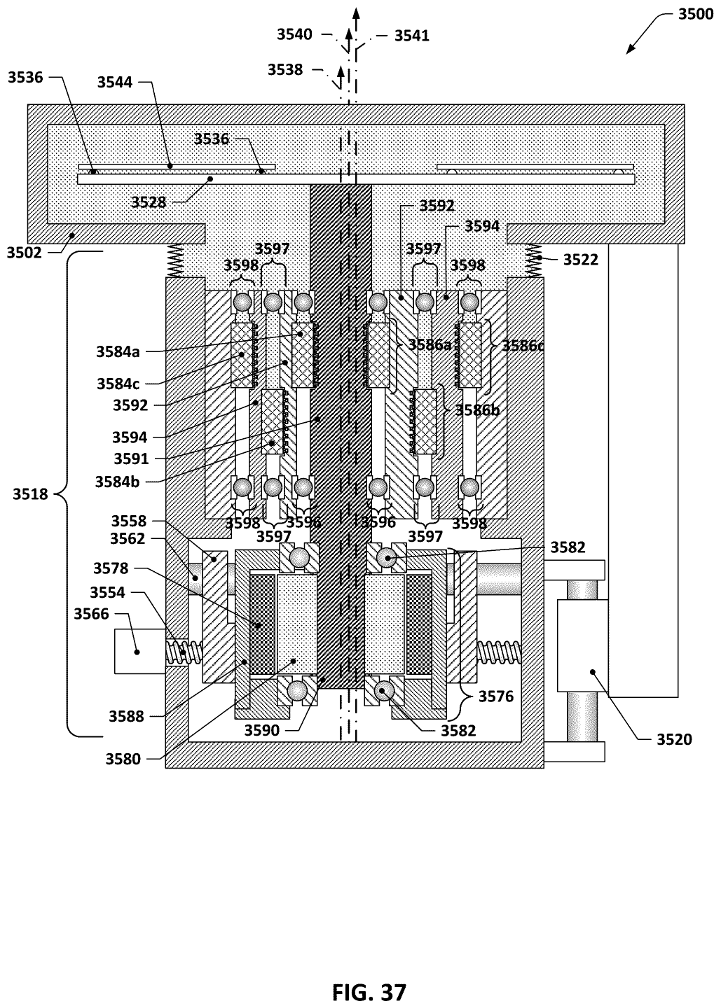

FIG. 37 depicts another example indexer system, similar to that of FIGS. 35 and 36, but having a lift capability that allows the entire indexer drive assembly 3518 to be moved up and down along the first axis using a lift actuator 3520. In such an implementation, a bellows seal 3522 may be placed between the chamber 3502 and, for example, a housing for the indexer drive assembly #IZ18 so as to maintain a vacuum environment within the chamber 3502.

As is apparent from the above discussion, there are several different implementations and concepts presented herein that may allow a rotational indexer to be equipped with the capability to individually adjust the placement of a wafer on a destination pedestal so as to more precisely center the wafer thereupon.

As mentioned previously, in some implementations, the target locations of the embarkation pedestals may be used as proxies for the estimated center locations of the wafers that are being transferred from the embarkation pedestals to respective destination pedestals. In other implementations, the actual center locations of the wafers may be evaluated, e.g., by one or more sensors, and used as the estimated center locations of the wafers. In such implementations, potential slippage of the wafers relative to the rotational indexer may be accounted for and corrected. For example, inertial effects and/or vibration may cause a wafer to shift slightly relative to the wafer support that supports it during rotation of the rotational indexer (and/or the rotational wafer support, if a rotational wafer support is used, relative to the indexer arm that supports it). Such slippage may, for example, be on the order of less than a millimeter, but may also, in some cases, exceed a millimeter, or even two or three millimeters. In implementations of the first technique that are used to correct for such wafer placement errors, the wafers may be placed on the ARA indexer using commensurately larger offsets between the wafer centers and the rotational centers of the rotatable wafer supports to allow for sufficient flexibility in terms of wafer placement to permit the wafers to be properly re-centered. In implementations of the second technique, e.g., in which the first axis of the rotational indexer is able to be translated along a lateral axis, the amount of translation that the mechanism that provides for such lateral translation may provide may similarly be increased in magnitude.

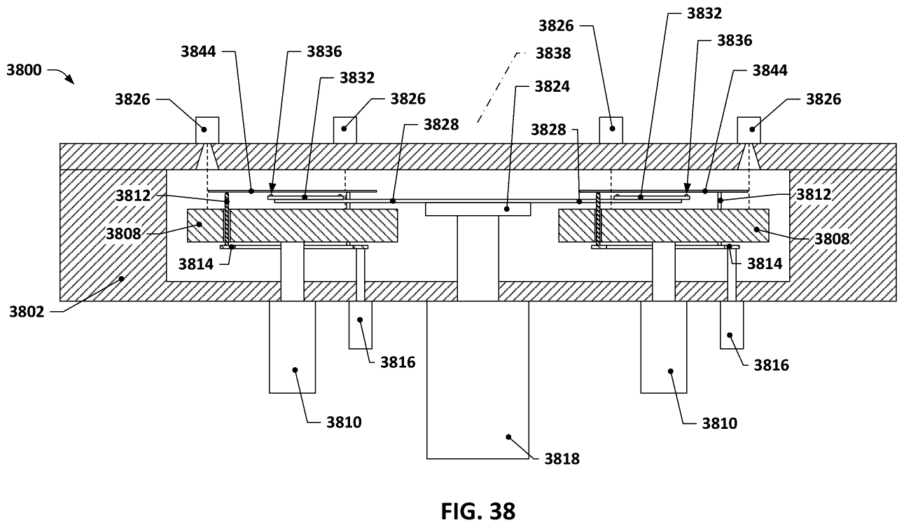

FIG. 38 depicts an example of a multi-station semiconductor processing tool that is similar to that of FIG. 2, but with the additional inclusion of wafer position sensors (and omission of some other elements, such as the lift system for the rotational indexer). In FIG. 38, the structures and elements that share the same last two digits in their callouts as components in FIG. 2 may generally be assumed to be equivalent to the structures in FIG. 2 that share those same last two digits in their callouts, and the description provided earlier with respect to FIG. 2 and those elements may be assumed to be applicable to the counterpart structures and elements in FIG. 38.

As mentioned, the semiconductor processing tool 3800 of FIG. 38 further includes wafer position sensors 3826, which may, for example, be image sensors or optical beam sensors that are oriented so as to be able to detect the edge of a wafer that is placed below the wafer position sensors 3826. Such wafer position sensors 3826 may obtain measurements of multiple locations along the edge of a single wafer, thereby allowing the location of the center of the wafer to be estimated. For example, if the wafer diameter is assumed to be known, then measuring the locations of two spaced-apart positions along the edge of the wafer may allow for two potential wafer center positions to be established using the centers of two circles of the same diameter as the wafer and which pass through both points-one of which will likely be easily discountable since it will be more off-center than the other. Similarly, if the locations of three spaced-apart positions along the wafer edge are determined, then this may allow the center location of the wafer to be determined by fitting a circle to those three points and using the center of the circle as the center of the wafer.

It will be understood that the wafer placement operations discussed herein for a specific wafer may be repeated for each wafer of a plurality of wafers that are being transferred between stations in a multi-station semiconductor processing tool. For example, in a given multi-station semiconductor processing tool, there may be N stations and the operations discussed above for a specific wafer may be performed M times, where M is greater than 1 and less than or equal to N. For example, in a four-station semiconductor processing tool, there may be four wafers present, but the above-discussed operations for transferring and centering a wafer on the target location for a given destination pedestal may only be performed for three of those four wafers, e.g., if the wafer at the fourth station is being removed from the tool and if a new wafer is being introduced to the tool in its place. The newly introduced wafer may, for example, be placed on the destination pedestal by, for example, a wafer handling robot such that it is already centered on that pedestal's target location.

It will also be appreciated that at least some of the rotation of the wafers about the first axis will occur simultaneously for a given set of wafers being transferred. As wafers are centered on the target locations at each destination pedestal and lifted off of the rotational indexer, the number of wafers being supported by the rotational indexer will decrease until the last wafer in the set is being centered on its respective destination pedestal. As a result, there may be some rotation of the rotational indexer about the first axis in which there is only one wafer being supported thereby, but there will also be at least some rotation of the rotational indexer about the first axis when the rotational indexer is supporting multiple wafers.

In some implementations, a controller may be provided as part of a multi-station chamber or tool, which may be part of the above-described examples. Such systems can comprise semiconductor processing equipment, including the processing tool or tools and/or chamber or chambers such as are described above, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the equipment disclosed herein, including, for example, rotational indexers, lift pins actuators, lift systems, and so forth.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer. With respect to the implementations discussed above, a controller may be provided with memory that stores computer-executable instructions for controlling one or more processors to perform various actions, e.g., such as are discussed above.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include multi-station plasma etch chambers or modules, multi-station deposition chambers or modules, multi-station spin-rinse chambers or modules, multi-station metal plating chambers or modules, multi-station clean chambers or modules, multi-station bevel edge etch chambers or modules, multi-station physical vapor deposition (PVD) chambers or modules, multi-station chemical vapor deposition (CVD) chambers or modules, multi-station atomic layer deposition (ALD) chambers or modules, multi-station atomic layer etch (ALE) chambers or modules, multi-station ion implantation chambers or modules, multi-station track chambers or modules, or any other systems with multi-station semiconductor processing chambers that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The terms “rotatably coupled” or “rotatably connected,” as used herein are to be understood to refer to a state in which the referenced items, e.g., a first item and a second item, are connected or coupled together in some physical manner, either directly, e.g., with the first item actually touching the second item, or indirectly, e.g., via one or more intervening components with the first item not touching the second item, such that the first item and/or the second item can rotate relative to the other of the first item and/or the second item. The term “coupled,” unless otherwise indicated by the context of its use, is to be understood to refer to a state in which two items are connected with one another in some manner, either directly, e.g., with the first item actually touching the second item, or indirectly, e.g., via one or more intervening components with the first item not touching the second item.

For example, a wheel hub that is coupled to a rotational output shaft of a motor may be directly mounted to the rotatable output shaft of the motor or may be indirectly coupled thereto by a belt that wraps around the wheel hub and the rotatable output shaft of the motor, gears that transmit torque from the motor to the wheel hub, one or more rotational couplers such as constant-velocity joints, universal joints, or flexible couplings, etc.

The phrase “movable relative to each other” or “rotatable relative to each other,” when used herein to refer to two items, is to be understood to refer to a situation in which one or both of the items are configured to be able to move or rotate relative to the other of the two items. For example, a first item that is mounted via a rotational bearing interface to a second item that is fixedly mounted to the ground would be considered to be “rotatable” or “movable” relative to the second item, and the second item would similarly be considered to be “rotatable” or “movable” relative to the first item (despite being fixed in place with respect to the earth).

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood.

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

It is to be further understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
a chamber,
a plurality of N semiconductor processing stations arranged in a nominally circular pattern within the chamber, each semiconductor processing station having a corresponding pedestal, and each pedestal having a corresponding target location, wherein the corresponding target location of each pedestal is representative of a location which, when a wafer is placed on that pedestal and centered on that pedestal's corresponding target location, results in that wafer being considered centered on that pedestal for a given semiconductor wafer processing operation;
a rotational indexer having a central hub and a plurality of N indexer arms, the central hub rotatable relative to the chamber about a first axis nominally located at the center of the circular pattern, each indexer arm having a proximal end fixedly mounted to the central hub and a distal end that supports a rotatable wafer support that is configured to rotate about a corresponding second axis relative to the indexer arms; and
a controller including one or more memory devices and one or more processors, wherein the one or more memory devices and the one or more processors are operatively connected and the one or more memory devices store computer-executable instructions which, when executed by the one or more processors, cause the one or more processors to:
a) select an embarkation pedestal from the plurality of pedestals,
b) select a destination pedestal from the plurality of pedestals,
c) select a selected rotatable wafer support from the plurality of rotatable wafer supports,
d) cause at least one of the central hub and the selected rotatable wafer support to rotate about the first axis and to rotate about the second axis of the selected rotatable wafer support relative to the indexer arms, respectively, such that a corresponding reference point that is fixed with respect to the selected rotatable wafer support and offset from the second axis of the selected rotatable wafer support by a first non-zero distance in a direction perpendicular to the second axis of the selected rotatable wafer support is centered on an estimated center of a wafer located at the semiconductor processing station associated with the embarkation pedestal when viewed along a direction parallel to the first axis,
e) cause the wafer located at the semiconductor processing station associated with the embarkation pedestal to be placed on the selected rotatable wafer support after the corresponding reference point for the selected rotatable wafer support is centered on the estimated center of the wafer located at the semiconductor procession station associated with the embarkation pedestal when viewed along a direction parallel to the first axis,
f) cause at least one of the central hub and the selected rotatable wafer support to rotate about the first axis and to rotate about the second axis of the selected rotatable wafer support relative to the indexer arms, respectively, such that the corresponding reference point for the selected rotatable wafer support is centered above the corresponding target location of the destination pedestal, and
g) cause the wafer on the selected rotatable wafer support to be lifted off of the selected rotatable wafer support after the corresponding reference point for the selected rotatable wafer support is centered above the corresponding target location of the destination pedestal.

2. The apparatus of claim 1, wherein the one or more memory devices further store additional computer-executable instructions which, when executed by the one or more processors, cause the one or more processors to, for a given set of M wafers, perform (a) through (g) M times, once for each wafer, wherein 2≤M≤N.

3. The apparatus of claim 2, wherein the one or more memory devices further store additional computer-executable instructions which, when executed by the one or more processors, cause the one or more processors to cause at least some rotation of the central hub about the first axis to occur for at least part of (d) and at least part of (f) simultaneously for all M wafers.

4. The apparatus of claim 2, wherein the one or more memory devices further store additional computer-executable instructions which, when executed by the one or more processors, cause at least one of the following to occur: (e) to be performed at different times for at least two of the M wafers and (g) to be performed at different times for at least two of the M wafers.

5. The apparatus of claim 2, wherein N=4 and 3≤M≤4.

6. The apparatus of claim 1, wherein the first distance is selected to be larger than twice an estimated maximum pedestal location tolerance within the chamber.

7. The apparatus of claim 1, wherein the one or more memory devices further store additional computer-executable instructions which, when executed by the one or more processors, cause the one or more processors to, for (d), use the corresponding target location of the embarkation pedestal as the estimated center of the wafer located at the semiconductor processing station associated with the embarkation pedestal.

8. The apparatus of claim 1, further comprising, for each semiconductor processing station, one or more corresponding wafer position sensors configured to obtain information from which a location of the center of a wafer placed on the pedestal of the corresponding semiconductor processing station can be determined, wherein the one or more memory devices further store additional computer-executable instructions which, when executed by the one or more processors, cause the one or more processors to:
h) determine, prior to (e), the location of the center of the wafer located at the semiconductor processing station associated with the embarkation pedestal using the information from the wafer position sensors for the corresponding wafer processing station, and
i) use, in (d), the location of the center of the wafer as determined in (h) as the estimated center of the wafer located at the semiconductor processing station associated with the embarkation pedestal.

9. The apparatus of claim 1, wherein the positions of the second axes relative to the central hub are not movable responsive to control signals caused to be sent by the one or more processors and no part of each rotatable wafer support is movable relative to the remainder of that rotatable wafer support responsive to control signals caused to be sent by the one or more processors.

10. The apparatus of claim 1, further comprising, at each semiconductor processing station, a corresponding lift pin mechanism with a corresponding plurality of lift pins, each lift pin mechanism configured to controllably extend and retract the corresponding plurality of lift pins such that uppermost surfaces of the corresponding plurality of lift pins are movable between at least locations above and below an uppermost surface of the pedestal of the corresponding semiconductor processing station.

11. The apparatus of claim 10, wherein the one or more memory devices further store additional computer-executable instructions which, when executed by the one or more processors, cause the one or more processors to, prior to performing (f):
h) cause any wafers being supported by the rotatable wafer supports other than the selected rotatable wafer support to each be placed on the lift pins of a corresponding one of the semiconductor processing stations, and
i) place one of the wafers on the selected rotatable wafer support when the selected rotatable wafer support is not supporting one of the wafers.

12. The apparatus of claim 11, wherein the one or more memory devices further store additional computer-executable instructions which, when executed by the one or more processors, cause the one or more processors to control the rotational indexer such that the indexer arms and the rotatable wafer supports are in a first configuration immediately prior to performing (h) and immediately before (i).

13. One or more non-transitory, computer-readable media storing computer-executable instructions for controlling one or more processors of a semiconductor processing tool having a chamber with a plurality of N semiconductor processing stations, each having a corresponding pedestal with a corresponding target location, arranged therewithin and a rotational indexer having a central hub and a plurality of N indexer arms each having a distal end that supports a corresponding rotatable wafer support, wherein the computer-executable instructions, when executed, cause the one or more processors to:
a) select an embarkation pedestal from the plurality of pedestals,
b) select a destination pedestal from the plurality of pedestals,
c) select a selected rotatable wafer support from the plurality of rotatable wafer supports,
d) cause at least one of the central hub and the selected rotatable wafer support to rotate about the first axis and to rotate about the second axis of the selected rotatable wafer support relative to the indexer arms, respectively, such that a corresponding reference point that is fixed with respect to the selected rotatable wafer support and offset from the second axis of the selected rotatable wafer support by a first non-zero distance in a direction perpendicular to the second axis of the selected rotatable wafer support is centered on an estimated center of a wafer located at the semiconductor processing station associated with the embarkation pedestal when viewed along a direction parallel to the first axis,
e) cause the wafer located at the semiconductor processing station associated with the embarkation pedestal to be placed on the selected rotatable wafer support after the corresponding reference point for the selected rotatable wafer support is centered on the estimated center of the wafer located at the semiconductor procession station associated with the embarkation pedestal when viewed along a direction parallel to the first axis,
f) cause at least one of the central hub and the selected rotatable wafer support to rotate about the first axis and to rotate about the second axis of the selected rotatable wafer support relative to the indexer arms, respectively, such that the corresponding reference point for the selected rotatable wafer support is centered above the corresponding target location of the destination pedestal, and
g) cause the wafer on the selected rotatable wafer support to be lifted off of the selected rotatable wafer support after the corresponding reference point for the selected rotatable wafer support is centered above the corresponding target location of the destination pedestal.

14. The one or more non-transitory, computer-readable media of claim 13, wherein the one or more non-transitory, computer-readable media further store additional computer-executable instructions which, when executed by the one or more processors, cause the one or more processors to, for a given set of M wafers, perform (a) through (g) M times, once for each wafer, wherein 2≤M≤N.

15. The one or more non-transitory, computer-readable media of claim 14, wherein the one or more non-transitory, computer-readable media further store additional computer-executable instructions which, when executed by the one or more processors, cause the one or more processors to cause at least some rotation of the central hub about the first axis to occur for at least part of (d) and at least part of (f) simultaneously for all M wafers.

16. The one or more non-transitory, computer-readable media of claim 14, wherein the one or more non-transitory, computer-readable media further store additional computer-executable instructions which, when executed by the one or more processors, cause at least one of the following to occur: (e) to be performed at different times for at least two of the M wafers and (g) to be performed at different times for at least two of the M wafers.

17. The one or more non-transitory, computer-readable media of claim 14, wherein N=4 and 3≤M≤4.

18. The one or more non-transitory, computer-readable media of claim 13, wherein the first distance is selected to be larger than twice an estimated maximum pedestal location tolerance within the chamber.

19. The one or more non-transitory, computer-readable media of claim 13, wherein the one or more non-transitory, computer-readable media further store additional computer-executable instructions which, when executed by the one or more processors, cause the one or more processors to, for (d), use the corresponding target location of the embarkation pedestal as the estimated center of the wafer located at the semiconductor processing station associated with the embarkation pedestal.

20. The one or more non-transitory, computer-readable media of claim 13, the one or more non-transitory, computer-readable media further store additional computer-executable instructions which, when executed by the one or more processors, cause the one or more processors to:
h) determine, prior to (e), the location of the center of the wafer located at the semiconductor processing station associated with the embarkation pedestal using information from one or more wafer position sensors for the corresponding wafer processing station, and
i) use, in (d), the location of the center of the wafer as determined in (h) as the estimated center of the wafer located at the semiconductor processing station associated with the embarkation pedestal.

21. The one or more non-transitory, computer-readable media of claim 13, wherein the one or more non-transitory, computer-readable media further store additional computer-executable instructions which, when executed by the one or more processors, cause the one or more processors to, prior to performing (f):
h) cause any wafers being supported by the rotatable wafer supports other than the selected rotatable wafer support to each be placed on lift pins of a corresponding one of the semiconductor processing stations, and
i) place one of the wafers on the selected rotatable wafer support when the selected rotatable wafer support is not supporting one of the wafers.

22. The one or more non-transitory, computer-readable media of claim 21, wherein the one or more non-transitory, computer-readable media further store additional computer-executable instructions which, when executed by the one or more processors, cause the one or more processors to control the rotational indexer such that the indexer arms and the rotatable wafer supports are in a first configuration immediately prior to performing (h) and immediately before (i).
